(19) United States
(12) Patent Application Publication
(10) Pub. No.: US 2025/0254995 A1
(43) Pub. Date: Aug. 7, 2025

(54) THIN-FILM TRANSISTOR ARRAY SUBSTRATE AND DISPLAY DEVICE INCLUDING SAME

(71) Applicant: LG Display Co., Ltd., Seoul (KR)

(72) Inventors: Jaeman Jang, Paju-si (KR); Uyhyun Choi, Paju-si (KR); Jinwon Jung, Paju-si (KR)

(73) Assignee: LG Display Co., Ltd., Seoul (KR)

(21) Appl. No.: 19/006,642

(22) Filed: Dec. 31, 2024

(30) Foreign Application Priority Data
Feb. 5, 2024 (KR) 10-2024-0017211

(51) Int. Cl. H10D 86/40; H10D 86/60

(52) U.S. Cl. CPC H10D 86/421; H10D 86/441; H10D 86/60

(57) ABSTRACT

A thin-film transistor array substrate and a display device including the same are discussed. The thin-film transistor array substrate can include a buffer layer disposed over a base substrate and a thin-film transistor. Parasitic capacitance is minimized by minimizing the area where the gate electrode overlaps the conductorization region. The breakdown characteristics of the thin-film transistor are improved by minimizing the overlapping area and improving the thickness uniformity of the gate insulating layer. The resolution and performance of the display device are improved by reducing the size of the thin-film transistor disposed in the display device while improving the characteristics of the thin-film transistor. The process steps and the masks are reduced and the process optimization is achieved. Further, the resistance of the gate electrode is reduced, the switching speed of the thin-film transistor is improved, and the power loss is reduced, thereby contributing to low power consumption.

### CROSS-REFERENCE TO RELATED APPLICATION

This application claims priority to Korean Patent Application No. 10-2024-0017211, filed in the Republic of Korea on Feb. 5, 2024, the entirety of which is hereby expressly incorporated by reference into the present application.

### BACKGROUND

### Technical Field

Embodiments of the present disclosure relate to a thin-film transistor array substrate and a display device including the same.

### Description of Related Art

With the development of the information society, a demand for various types of display devices for displaying images is increasing. As such, a range of display devices, such as liquid crystal display (LCD) devices, plasma display devices, and organic light-emitting diode display devices, have recently come into use.

A large number of thin-film transistors are disposed on a display panel, which is a core component of a display device, to drive the display panel. For example, to drive the light-emitting elements of an organic light-emitting display device, driving thin-film transistors and switching thin-film transistors are disposed on the display panel.

### SUMMARY OF THE DISCLOSURE

Various aspects of the present disclosure provide a thin-film transistor array substrate and a display device including the same, in which parasitic capacitance between a gate electrode and a conductorization region of a thin-film transistor can be minimized and the breakdown characteristics of the thin-film transistor can be improved.

Also aspects of the present disclosure provide a thin-film transistor array substrate and a display device including the same, in which the resolution and performance of the display device can be improved.

The objectives of the present disclosure are not limited to the aforementioned description, and other objectives not explicitly disclosed herein will be clearly understood by those having ordinary knowledge in the technical field to which the present disclosure pertains from the description provided hereinafter.

According to embodiments of the present disclosure, a thin-film transistor array substrate includes a buffer layer disposed over a base substrate, and including an open area exposing a portion of the base substrate and a first slope having an inverted tapered shape and exposed through the open area; and a first thin-film transistor. The first thin-film transistor includes a first active pattern including a first channel region including a first portion disposed over the first slope of the buffer layer and a second portion disposed over a top surface of the base substrate under the first slope of the buffer layer, a first conductorization region disposed over a top surface of the buffer layer, and a second conductorization region disposed over the top surface of the base substrate; a first gate insulating layer including a first slope portion disposed over the first portion of the first channel region and a first horizontal portion disposed over the second portion of the first channel region; and a first gate electrode disposed over the first slope portion and the first horizontal portion of the first gate insulating layer and overlapping the first channel region.

According to embodiments of the present disclosure, a display device includes a circuit element layer disposed over a base substrate; and an emitting element disposed over the circuit element layer. The circuit element layer includes a buffer layer disposed over the base substrate, and including an open area exposing a portion of the base substrate and a first slope having an inverted tapered shape and exposed through the open area; and a first thin-film transistor. The first thin-film transistor includes a first active pattern including a first channel region including a first portion disposed over the first slope of the buffer layer and a second portion disposed over a top surface of the base substrate under the first slope of the buffer layer, a first conductorization region disposed over a top surface of the buffer layer, and a second conductorization region disposed over the top surface of the base substrate; a first gate insulating layer including a first slope portion disposed over the first portion of the first channel region and a first horizontal portion disposed over the second portion of the first channel region; and a first gate electrode disposed over the first slope portion and the first horizontal portion of the first gate insulating layer and overlapping the first channel region.

According to embodiments of the present disclosure, a thin-film transistor array substrate and a display device including the same can be provided, in which parasitic capacitance can be reduced by minimizing the area where a gate electrode overlaps a conductorization region.

According to embodiments of the present disclosure, a thin-film transistor array substrate and a display device including the same can be provided, in which the breakdown characteristics of a thin-film transistor can be improved by minimizing the area where the gate electrode overlaps the conductorization region and improving the thickness uniformity of the gate insulating layer.

According to embodiments of the present disclosure, a thin-film transistor array substrate and a display device including the same can be provided, in which the resolution and performance of the display device can be improved by reducing the size of the thin-film transistor disposed in the display device while improving the characteristics of the thin-film transistor.

According to embodiments of the present disclosure, a thin-film transistor array substrate and a display device including the same can be provided, in which the number of process steps and the number of masks can be reduced by forming a vertical thin-film transistor and a co-planar thin-film transistor at the same time. Accordingly, the effect of process optimization can be achieved.

According to embodiments of the present disclosure, a thin-film transistor array substrate and a display device including the same can be provided, in which by forming a gate connecting electrode connected to the gate electrode, the resistance of the gate electrode can be reduced and the switching speed of the thin-film transistor can be improved, and the power loss occurring during the switching process can be reduced, thereby contributing to low power consumption.

The effects of the present disclosure are not limited to the aforementioned description, and other effects not explicitly disclosed herein will be clearly understood by those having ordinary knowledge in the technical field, to which the present disclosure pertains, from the description

### BRIEF DESCRIPTION OF THE DRAWINGS

The above and other objectives, features, and advantages of the present disclosure will be more clearly understood from the following detailed description, taken in conjunction with the accompanying drawings, in which:

FIG. 1 is a plan view illustrating a thin-film transistor array substrate according to embodiments of the present disclosure;

FIG. 2 is a cross-sectional view taken along line A-A′ in FIG. 1;

FIG. 3 is a cross-sectional view taken along line B-B′ in FIG. 1;

FIGS. 4 and 5 each illustrate a gate electrode of a thin-film transistor according to some embodiments of the present disclosure;

FIG. 6 is a plan view illustrating a thin-film transistor array substrate according to embodiments of the present disclosure;

FIG. 7 is a cross-sectional view taken along line C-C′ in FIG. 6;

FIG. 8 is a cross-sectional view taken along line D-D′ in FIG. 6;

FIG. 9 illustrates a schematic configuration of a system of a display device according to embodiments of the present disclosure;

FIG. 10 is a cross-sectional view illustrating a display device according to embodiments of the present disclosure;

FIG. 11 is a plan view illustrating a circuit element layer of the display device according to embodiments of the present disclosure;

FIG. 12 is a cross-sectional view taken along line E-E′ in FIG. 11; and

FIGS. 13A through 19B are cross-sectional views illustrating a method of fabricating a circuit element layer of a display device according to embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments of the present disclosure that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. Further, the term “can” fully encompasses all the meanings and coverages of the term “may,” and the terms “invention” and “disclosure” are interchangeably used herein.

The terms such as “including”, “having”, “containing”, “constituting”, “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, a variety of embodiments of the present disclosure will be described in detail with reference to the accompanying drawings. All the components of each substrate and each display device according to all embodiments of the present disclosure are operatively coupled and configured.

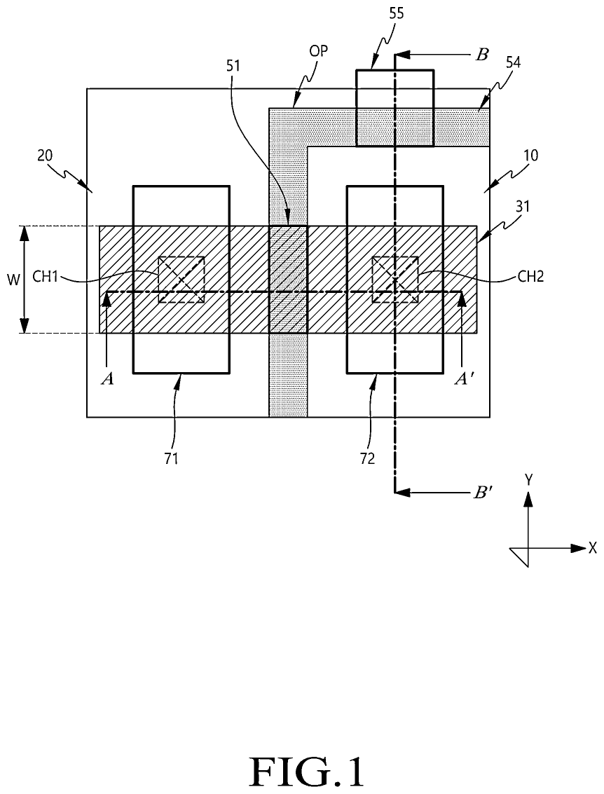

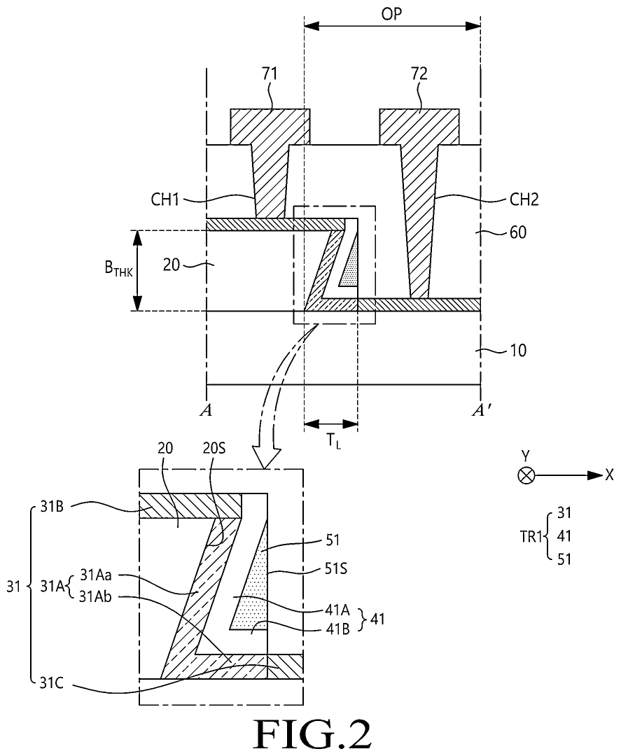

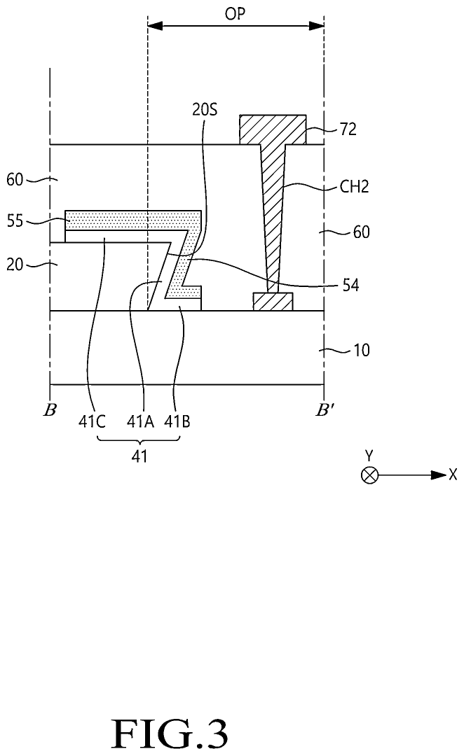

FIG. 1 is a plan view illustrating a thin-film transistor array substrate according to embodiments of the present disclosure, FIG. 2 is a cross-sectional view taken along line A-A′ in FIG. 1, and FIG. 3 is a cross-sectional view taken along line B-B′ in FIG. 1.

Referring now to FIGS. 1 through 3, a buffer layer 20 having an open area OP exposing a portion of a substrate 10 can be disposed over the substrate 10.

The open area OP can expose a slope 20S of the buffer layer 20. The width of the open area OP can increase in the direction toward the substrate 10. The slope 20S can have a reverse tapered shape.

A thin-film transistor TR1 can be disposed over a region of the buffer layer 20 including the slope 20S. The thin-film transistor TR1 can be a vertical thin-film transistor. The thin-film transistor TR1 can include an active pattern 31, a gate insulating layer 41, and a gate electrode 51.

The active pattern 31 can be disposed over the slope 20S of the buffer layer 20, and can extend to the top surface of the buffer layer 20 adjacent to the slope 20S of the buffer layer 20 and to the top surface of the substrate 10. From a planar view, the active pattern 31 can traverse the slope 20S of the buffer layer 20. The active pattern 31 can traverse the slope 20S of the buffer layer 20 in the X-axis direction X of the X-Y plane, but is not limited thereto.

The active pattern 31 can be formed by an atomic layer deposition (ALD) process having excellent step coverage. The active pattern 31 can be provided as a thin film along the surface curvatures of the slope 20S of the buffer layer 20, the top surface of the buffer layer 20, and the top surface of the substrate 10.

The active pattern 31 can be formed of an oxide semiconductor. The oxide semiconductor can include an oxide of a metal, such as zinc (Zn), indium (In), gallium (Ga), tin (Sn), or titanium (Ti), or a combination of a metal, such as zinc (Zn), indium (In), gallium (Ga), tin (Sn), or titanium (Ti), and an oxide thereof. More specifically, oxide semiconductors can include zinc oxide (ZnO), zinc-tin oxide (ZTO), zinc-indium oxide (ZIO), indium oxide (InO), titanium oxide (TiO) indium-gallium-zinc oxide (IGZO), indium-zinc-tin oxide (IZTO), and the like.

The active pattern 31 can include a channel region 31A, a first conductorization region 31B, and a second conductorization region 31C.

The channel region 31A can have semiconductor properties. The channel region 31A can be formed of, for example, an oxide semiconductor. The first conductorization region 31B and the second conductorization region 31C can be regions where the oxide semiconductor has been conductorized by exposure to an etch gas used in an etching process of forming the gate insulating layer 41.

The channel region 31A can be disposed over the slope 20S of the buffer layer 20. In addition, the channel region 31A can be disposed over the top surface of the substrate 10 under the slope 20S of the buffer layer 20. The channel region 31A can include a first portion 31Aa disposed over the slope 20S of the buffer layer 20 and a second portion 31Ab disposed over the top surface of the substrate 10.

The channel width W_{ch} of the thin-film transistor TR1 can have a size equal to the width W in the Y-axis direction Y of the channel region 31A. The channel length L_{ch} of the thin-film transistor TR1 can be defined as shown in the following Equation 1.

$${L}_{ch} = {( {B}_{{THK}^{2}} + {T}_{L}^{2} )}^{\frac{1}{2}} + {T}_{L} \qquad [ Equation 1 ]$$

Here, B_{THK} is the thickness of the buffer layer 20, and T_{L} is the length in the X-axis direction X of the second portion 31Ab of the channel region 31A. The sizes of B_{THK} and T_{L} can be set such that the channel length L_{ch} of the thin-film transistor TR1 is a target value.

The first conductorization region 31B can be disposed over the top surface of the buffer layer 20 on one side of the channel region 31A. The second conductorization region 31C can be disposed over the top surface of the substrate 10 on the other side of the channel region 31A. One of the first conductorization region 31B and the second conductorization region 31C can be a source region of the thin-film transistor TR1, and the other can be a drain region of the thin-film transistor TR1.

A portion of the first conductorization region 31B can overlap the slope 20S of the buffer layer 20. The second conductorization region 31C may not overlap the slope 20S of the buffer layer 20. The first conductorization region 31B and the second conductorization region 31C can be spaced apart from each other in a horizontal direction parallel to the top surface of the substrate 10.

The gate insulating layer 41 can be disposed over the channel region 31A. The gate insulating layer 41 can expose the first conductorization region 31B and the second conductorization region 31C.

The gate insulating layer 41 can include a slope portion 41A, a horizontal portion 41B, and an extension portion 41C.

The slope portion 41A of the gate insulating layer 41 can be disposed over the first portion 31A of the channel region 31A to cover the first portion 31A of the channel region 31A. The slope portion 41A of the gate insulating layer 41 can extend to the slope 20S of the buffer layer 20 on opposite sides of the channel region 31A to cover the slope 20S of the buffer layer 20.

A portion of the slope portion 41A of the gate insulating layer 41 can be in direct contact with the first portion 31Aa of the channel region 31A, and another portion of the slope portion 41A of the gate insulating layer 41 can be in direct contact with the slope 20S of the buffer layer 20. A portion of the top portion of the slope portion 41A of the gate insulating layer 41 can be in contact with a side surface of the first conductorization region 31B.

The horizontal portion 41B of the gate insulating layer 41 can be disposed over the second portion 31Ab of the channel region 31A to cover the second portion 31Ab of the channel region 31A. The horizontal portion 41B of the gate insulating layer 41 can extend to the substrate 10 on opposite sides of the channel region 31A to cover the top surface of the substrate 10 under the slope portion 41A of the gate insulating layer 41.

A portion of the horizontal portion 41B of the gate insulating layer 41 can be in direct contact with the second portion 31Ab of the channel region 31A, and another portion of the horizontal portion 41B of the gate insulating layer 41 can be in direct contact with the top surface of the substrate 10.

The extension portion 41C of the gate insulating layer 41 can be disposed over the top surface of the buffer layer 20 around the open area OP, and can extend to the open area OP to be connected to the slope portion 41A of the gate insulating layer 41.

The gate insulating layer 41 can be formed by the ALD process. Since the gate insulating layer 41 is formed by the ALD process with excellent step coverage, the gate insulating layer 41 can have a uniform thickness. As a result, the breakdown characteristics of the thin-film transistor TR1 can be improved by preventing the gate insulating layer 41 from being formed with an excessively thin thickness at vulnerable points such as corner portions.

The gate electrode 51 and a gate connecting electrode 54 can be disposed under the slope portion 41A of the gate insulating layer 41. The gate electrode 51 and the gate connecting electrode 54 can be connected to each other.

The gate electrode 51 can be disposed over a portion of the slope portion 41A of the gate insulating layer 41 that is in direct contact with the first portion 31Aa of the channel region 31A and over a portion of the horizontal portion 41B of the gate insulating layer 41 that is in direct contact with the second portion 31Ab of the channel region 31A. The gate electrode 51 can overlap the channel region 31A of the active pattern 31.

The gate connecting electrode 54 can be disposed over another portion of the slope portion 41A of the gate insulating layer 41 in direct contact with the slope 20S of the buffer layer 20 and over another portion of the horizontal portion 41B of the gate insulating layer 41 in direct contact with the top surface of the substrate 10. The gate connecting electrode 54 may not overlap the active pattern 31.

A gate connecting line 55 can be disposed over the extension portion 41C of the gate insulating layer 41. The gate connecting line 55 can extend to the open area OP to be connected to the gate connecting electrode 54. The gate connecting line 55 may not overlap the active pattern 31.

The gate electrode 51, the gate connecting electrode 54, and the gate connecting line 55 can be formed of the same material. The gate electrode 51, the gate connecting electrode 54, and the gate connecting line 55 can be implemented using one of various metallic materials, such as molybdenum (Mo), aluminum (Al), chromium (Cr), gold (Au), titanium (Ti), nickel (Ni), neodymium (Nd), or copper (Cu), an alloy of one or more thereof, or multiple layers thereof, but are not limited thereto.

The gate electrode 51, the gate connecting electrode 54, and the gate connecting line 55 can be formed by forming a gate electrode layer, forming a mask pattern covering a portion of the periphery of the open area OP, and etching the gate electrode layer using the mask pattern as an etch mask.

In the etching process, the gate electrode layer covered with the slope portion 41A of the gate insulating layer 41 can remain unetched, thereby forming the gate electrode 51 and the gate connecting electrode 54. In the etching process, the gate electrode layer covered with the mask pattern can remain unetched, thereby forming the gate connecting line 55.

The gate electrode 51 can have an inner surface in contact with the slope portion 41A and the horizontal portion 41B of the gate insulating layer 41 and an outer surface 51S opposite the inner surface.

As described above, a portion of the top portion of the slope portion 41A of the gate insulating layer 41 can be in contact with a side surface of the first conductorization region 31B. The outer surface 51S of the gate electrode 51 can be vertically aligned with a portion of the top portion of the slope portion 41A of the gate insulating layer 41.

A portion of the first conductorization region 31B can be self-aligned with the slope portion 41A of the gate insulating layer 41. A portion of the second conductorization region 31C can be self-aligned with the horizontal portion 41B of the gate insulating layer 41. The first conductorization region 31B may not overlap the gate electrode 51, or only a portion of the first conductorization region 31B can overlap the gate electrode 51. The second conductorization region 31C may not overlap the gate electrode 51.

The area of the first and second conductorization regions 31B and 31C overlapping the gate electrode 51 can be minimized by disposing the gate electrode 51 over the gate insulating layer 41 and configuring the first conductorization region 31B and the second conductorization region 31C to be self-aligned with the gate insulating layer 41. Accordingly, parasitic capacitance between the gate electrode 51 and the first and second conductorization regions 31B and 31C can be minimized, and the breakdown characteristics of the thin-film transistor TR1 can be improved.

An insulating layer 60 can be disposed over the buffer layer 20 to cover the active pattern 31, the gate insulating layer 41, the gate electrode 51, the gate connecting electrode 54, and the gate connecting line 55. The insulating layer 60 can have a first contact hole CH1 exposing a first conductorization region 31B and a second contact hole CH2 exposing a second conductorization region 31C.

A first electrode 71 and a second electrode 72 can be disposed over the insulating layer 60. The first electrode 71 can be connected to the first conductorization region 31B through the first contact hole CH1. The second electrode 72 can be connected to the second conductorization region 31C through the second contact hole CH2.

FIG. 2 illustrates, but is not limited to, a case in which the outer surface 51S of the gate electrode 51 is vertically aligned with the top portion of the slope portion 41A of the gate insulating layer 41. The shape of the outer surface 51S of the gate electrode 51 can vary depending on the thickness of the gate electrode layer, the processing conditions of the process of etching the gate electrode layer, and the like.

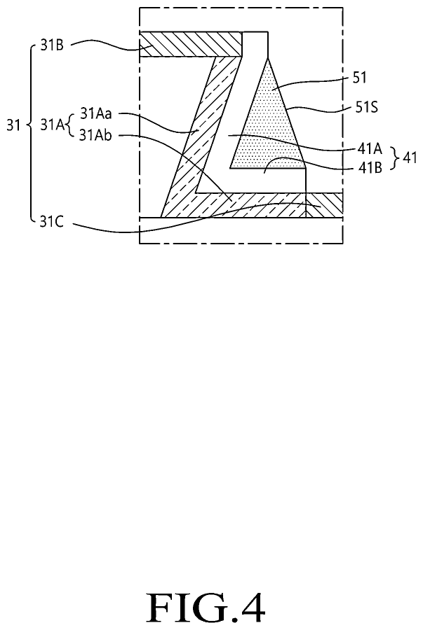

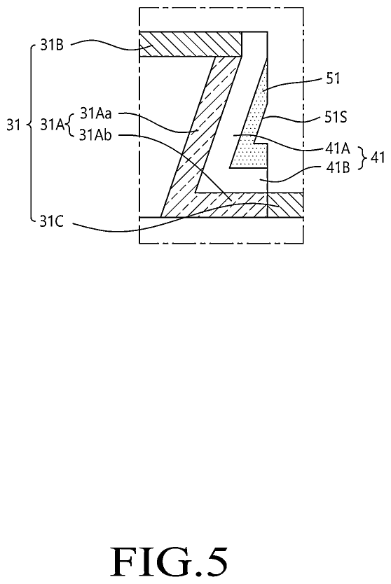

FIGS. 4 and 5 each illustrate a gate electrode of a thin-film transistor according to some embodiments of the present disclosure.

Referring to FIG. 4, the outer surface 51S of the gate electrode 51 can have a regular tapered shape.

As described above, the gate electrode 51 can be formed by forming a gate electrode layer and etching the gate electrode layer by an etching process. The gate electrode layer disposed under the slope portion 41A of the gate insulating layer 41 can be covered with the slope portion 41A so as not to be removed and remain in the etching process, thereby forming the gate electrode 51.

The outer surface 51S of the gate electrode 51 is a surface formed by the above etching process, and due to process factors, the gate electrode layer can be etched in an inclined shape rather than a vertical shape, thereby causing the outer surface 51S of the gate electrode 51 to have a tapered shape. In such a case, the outer surface 51S of the gate electrode 51 can protrude beyond (or above) the top portion of the slope portion 41A of the gate insulating layer 41.

Referring to FIG. 5, the outer surface 51S of the gate electrode 51 can have a bend corresponding to the surface shape of the slope portion 41A and the horizontal portion 41B of the gate insulating layer 41.

In the process of forming the gate electrode layer, the gate electrode layer may not completely fill the space under the slope portion 41A of the gate insulating layer 41 and can be formed along the surface bend of the slope portion 41A and the horizontal portion 41B of the gate insulating layer 41. In such a case, the outer surface 51S of the gate electrode 51 can have a bend corresponding to the surface shape of the slope portion 41A and the horizontal portion 41B of the gate insulating layer 41.

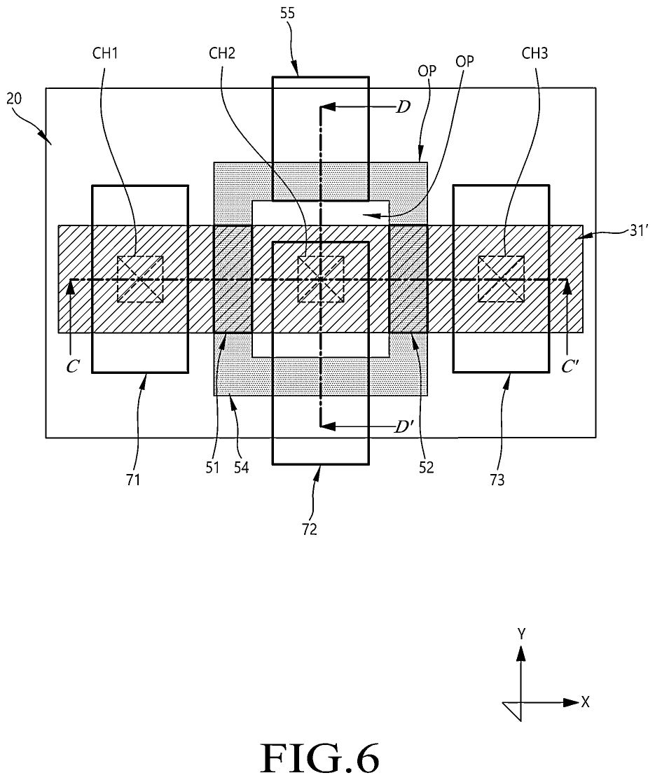

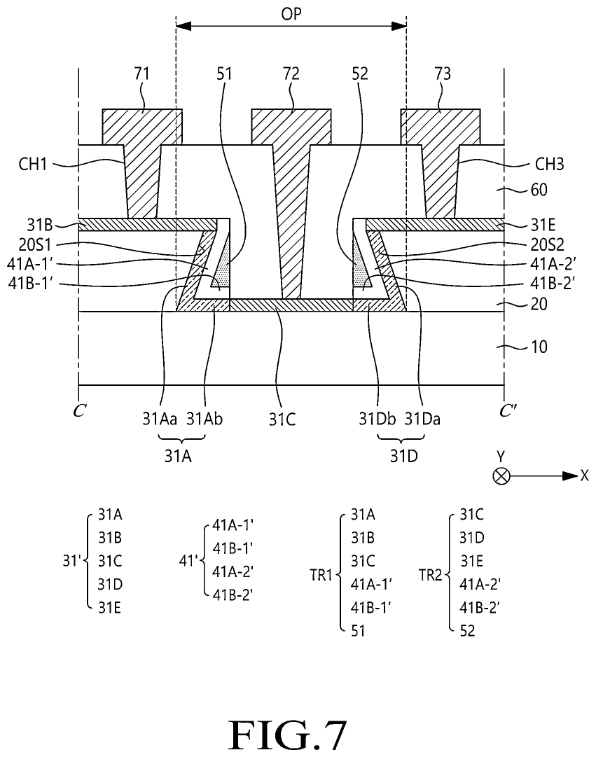

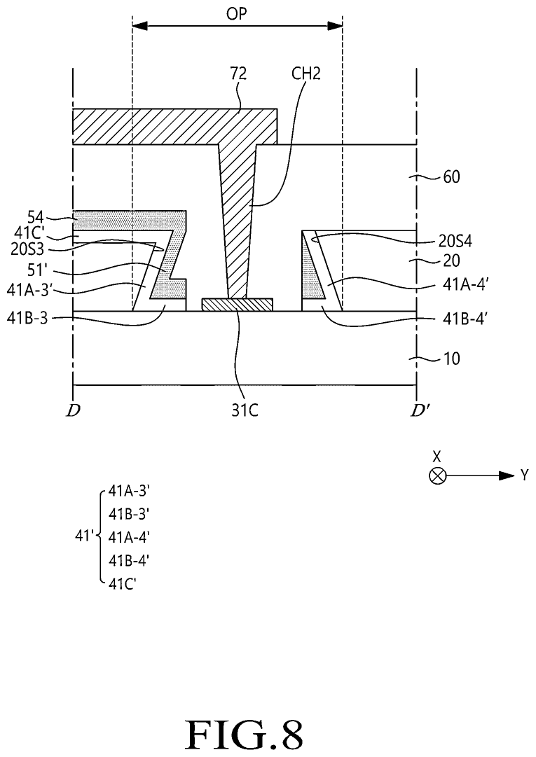

FIG. 6 is a plan view illustrating a thin-film transistor array substrate according to embodiments of the present disclosure, FIG. 7 is a cross-sectional view taken along line C-C′ in FIG. 6, and FIG. 8 is a cross-sectional view taken along line D-D′ in FIG. 6.

Referring to FIGS. 6 through 8, a buffer layer 20 having an open area OP exposing a portion of the substrate 10 can be disposed over the substrate 10.

Slopes 20S1, 20S2, 20S3, and 20S4 of the buffer layer 20 can be exposed through the open area OP. The slopes 20S1, 20S2, 20S3, and 20S4 of the buffer layer 20 can include first and second slopes 20S1 and 20S2 facing each other in the X-axis direction X of the X-Y plane, and third and fourth slopes 20S3 and 20S4 facing each other in the Y-axis direction Y of the X-Y plane. The width of the open area OP can increase in the direction toward the substrate 10. The first, second, third, and fourth slopes 20S1, 20S2, 20S3, and 20S4 of the buffer layer 20 can have an inverted tapered shape.

In the present disclosure, the first and second slopes 20S1 and 20S2 of the buffer layer 20 face each other in the X-axis direction X and the third and fourth slopes 20S3, 20S4 of the buffer layer 20 face each other in the Y-axis direction Y, but this is not intended to be limiting. The first and second slopes 20S1 and 20S2 of the buffer layer 20 can face each other in a first direction, and the third and fourth slopes 20S3 and 20S4 of the buffer layer 20 can face each other in a second direction intersecting the first direction.

A first thin-film transistor TR1 can be disposed over a region including the first slope 20S1 of the buffer layer 20. A second thin-film transistor TR2 can be disposed over a region including the second slope 20S2 of the buffer layer 20. The first and second thin-film transistors TR1 and TR2 can be vertical thin-film transistors.

A first active pattern 31′ can be disposed continuously over the top surface of the buffer layer 20 adjacent to the first slope 20S1 of the buffer layer 20, over the first slope 20S1 of the buffer layer 20, over the top surface of the substrate 10 between the first slope 20S1 and the second slope 20S2 of the buffer layer 20, over the second slope 20S2 of the buffer layer 20, and over the top surface of the buffer layer 20 adjacent to the second slope 20S2 of the buffer layer 20. In a plan view, the first active pattern 31′ can traverse the first and second slopes 20S1 and 20S2 of the buffer layer 20 in the X-axis direction X.

The first active pattern 31′ can be provided as a thin film along the surface curvatures of the first and second slopes 20S1 and 20S2 of the buffer layer 20, the top surface of the buffer layer 20, and the top surface of the substrate 10.

The first active pattern 31′ can be formed of an oxide semiconductor. The first active pattern 31′ can include a first channel region 31A, a first conductorization region 31B, a second conductorization region 31C, a second channel region 31D, and a third conductorization region 31E.

The first and second channel regions 31A and 31D can have semiconductor properties. The first and second channel regions 31A and 31D can be formed of, for example, a oxide semiconductor. The first, second, and third conductorization regions 31B, 31C, and 31E can be regions in which the oxide semiconductor is conductorized by exposure to an etch gas used in an etching process to form a first gate insulating layer 41′.

The first channel region 31A can be disposed over the first slope 20S1 of the buffer layer 20. In addition, the first channel region 31A can be disposed over the top surface of the substrate 10 under the first slope 20S1 of the buffer layer 20. The first channel region 31A can include a first portion 31Aa disposed over the first slope 20S1 of the buffer layer 20 and a second portion 31Ab disposed over the top surface of the substrate 10.

The second channel region 31B can be disposed over the second slope 20S2 of the buffer layer 20. The second channel region 31B can also be disposed over the top surface of the substrate 10 under the second slope 20S2 of the buffer layer 20. The second channel region 31B can include a third portion 31Ba disposed over the second slope 20S2 of the buffer layer 20 and a fourth portion 31Bb disposed over the top surface of the substrate 10.

The first conductorization region 31B can be disposed over the top surface of the buffer layer 20 on one side of the first channel region 31A. The second conductorization region 31C can be disposed over the top surface of the substrate 10 between the other side of the first channel region 31A and one side of the second channel region 31B. The third conductorization region 31E can be disposed over the top surface of the buffer layer 20 on the other side of the second channel region 31D.

The first conductorization region 31B and the second conductorization region 31C can be disposed on opposite sides of the first channel region 31A in the X-axis direction X. The second conductorization region 31C and the third conductorization region 31E can be disposed on opposite sides of the second channel region 31D in the X-axis direction X. The second conductorization region 31C can be disposed between the first channel region 31A and the second channel region 31D in the X-axis direction X.

One of the first conductorization region 31B and the second conductorization region 31C can be a source region of the first thin-film transistor TR1, and the other can be a drain region of the first thin-film transistor TR1. One of the second conductorization region 31C and the third conductorization region 31E can be a source region of the second thin-film transistor TR2 and the other can be a drain region of the second thin-film transistor TR2. The first thin-film transistor TR1 and the second thin-film transistor TR2 can share the second conductorization region 31C.

The first conductorization region 31B can overlap the first slope 20S1 of the buffer layer 20. The third conductorization region 31E can overlap the second slope 20S2 of the buffer layer 20. The second conductorization region 31C can overlap none of the slopes 20S1, 20S2, 20S3, and 20S4 of the buffer layer 20. The first conductorization region 31B, the second conductorization region 31C, and the third conductorization region 31E can be spaced apart from each other in a horizontal direction parallel to the top surface of the substrate 10.

The first gate insulating layer 41′ can be disposed over the first and second channel regions 31A and 31D. The first gate insulating layer 41′ can expose the first, second, and third conductorization regions 31B, 31C, and 31E.

The first gate insulating layer 41′ can include first, second, third, and fourth slope portions 41A-1′, 41A-2′, 41A-3′, and 41A-4′ and first, second, third, and fourth horizontal portions 41B-1′, 41B-2′, 41B-3′, and 41B-4′. The first gate insulating layer 41′ can further include an extension portion 41C.

The first slope portion 41A-1′ of the first gate insulating layer 41′ can cover the first portion 31Aa of the first channel region 31A. The first slope portion 41A-1′ of the gate insulating layer 41′ can extend to the first slope 20S1 of the buffer layer 20 on opposite sides of the first channel region 31A to cover the first slope 20S1 of the buffer layer 20.

A portion of the first slope portion 41A-1′ of the first gate insulating layer 41′ can be in direct contact with the first portion 31Aa of the first channel region 31A, and another portion of the first slope portion 41A-1′ of the first gate insulating layer 41′ can be in direct contact with the first slope 20S1 of the buffer layer 20. A portion of the top portion of the first slope portion 41A-1′ of the first gate insulating layer 41′ can be in contact with a side surface of the first conductorization region 31B.

The first horizontal portion 41B-1′ of the first gate insulating layer 41′ can cover the second portion 31Ab of the first channel region 31A. The first horizontal portion 41B-1′ of the first gate insulating layer 41′ can extend to the top surface of the substrate 10 to cover the top surface of the substrate 10 under the first slope portion 41A-1′ of the first gate insulating layer 41′.

A portion of the first horizontal portion 41B-1′ of the first gate insulating layer 41′ can be in direct contact with the second portion 31Ab of the first channel region 31A, and another portion of the first horizontal portion 41B-1′ of the first gate insulating layer 41′ can be in direct contact with the top surface of the substrate 10.

The second slope portion 41A-2′ of the first gate insulating layer 41′ can cover the third portion 31Da of the second channel region 31D. The second slope portion 41A-2′ of the first gate insulating layer 41′ can extend to the second slope 20S2 of the buffer layer 20 on opposite sides of the second channel region 31D to cover the second slope 20S2 of the buffer layer 20.

A portion of the second slope portion 41A-2′ of the first gate insulating layer 41′ can be in direct contact with the third portion 31Da of the second channel region 31D, and another portion of the second slope portion 41A-2′ of the first gate insulating layer 41′ can be in direct contact with the second slope 20S2 of the buffer layer 20. A portion of the top portion of the second slope portion 41A-2′ of the first gate insulating layer 41′ can be in contact with a side surface of the third conductorization region 31E.

The second horizontal portion 41B-2′ of the first gate insulating layer 41′ can cover the fourth portion 31Db of the second channel region 31D. The second horizontal portion 41B-2′ of the first gate insulating layer 41′ can extend to the top surface of the substrate 10 to cover the top surface of the substrate 10 under the second slope portion 41A-2′ of the first gate insulating layer 41′.

A portion of the second horizontal portion 41B-2′ of the first gate insulating layer 41′ can be in direct contact with the fourth portion 31Db of the second channel region 31D, and another portion of the second horizontal portion 41B-2′ of the first gate insulating layer 41′ can be in direct contact with the top surface of the substrate 10.

The third slope portion 41A-3′ of the first gate insulating layer 41′ can cover the third slope 20S3 of the buffer layer 20. The third slope portion 41A-3′ of the first gate insulating layer 41′ can be in direct contact with the third slope 20S3 of the buffer layer 20.

The third horizontal portion 41B-3′ of the first gate insulating layer 41′ can cover the top surface of the substrate 10 under the third slope portion 41A-3′. The third horizontal portion 41B-3′ of the first gate insulating layer 41′ can be in direct contact with the top surface of the substrate 20 under the third slope portion 41A-3′ of the first gate insulating layer 41′.

The fourth slope portion 41A-4′ of the first gate insulating layer 41′ can cover the fourth slope 20S4 of the buffer layer 20. The fourth slope portion 41A-4′ of the first gate insulating layer 41′ can be in direct contact with the fourth slope 20S4 of the buffer layer 20.

The fourth horizontal portion 41B-4′ of the first gate insulating layer 41′ can cover the top surface of the substrate 10 under the fourth slope portion 41A-4′ of the first gate insulating layer 41′. The fourth horizontal portion 41B-4′ of the first gate insulating layer 41′ can be in direct contact with the top surface of the substrate 10 under the fourth slope portion 41A-4′ of the first gate insulating layer 41′.

The extension portion 41C of the first gate insulating layer 41′ can be disposed over the top surface of the buffer layer 20 around the open area OP, and can extend to the open area OP to be connected to the third slope portion 41A-3′ of the first gate insulating layer 41′. In the present disclosure, the extension portion 41C of the first gate insulating layer 41′ is connected to the third slope portion 41A-3′ of the first gate insulating layer 41′, but is not limited thereto. The extension portion 41C of the first gate insulating layer 41′ can be connected to at least one of the first, second, third, fourth slope portions 41A-1′, 41A-2′, 41A-3′, and 41A-4′ of the first gate insulating layer 41′.

The first gate insulating layer 41′ can be formed by the ALD process. Since the first gate insulating layer 41′ is formed by the ALD process with good step coverage, the first gate insulating layer 41′ can have a uniform thickness.

First and second gate electrodes 51 and 52 and a gate connecting electrode 54 can be disposed under the first, second, third, and fourth slope portions 41A-1′, 41A-2′, 41A-3′, and 41A-4′ of the first gate insulating layer 41′.

The first gate electrode 51 can be disposed over a portion of the first slope portion 41A-1′ of the first gate insulating layer 41′ that is in direct contact with the first portion 31Aa of the first channel region 31A. In addition, the first gate electrode 51 can be disposed over a portion of the first horizontal portion 41B-1′ of the gate insulating layer 41′ that is in direct contact with the second portion 31Ab of the first channel region 31A. The first gate electrode 51 can overlap the first channel region 31A.

The second gate electrode 52 can be disposed over a portion of the second slope portion 41A-2′ of the first gate insulating layer 41′ that is in direct contact with the third portion 31Da of the second channel region 31D. In addition, the second gate electrode 52 can be disposed over a portion of the second horizontal portion 41B-2′ of the gate insulating layer 41′ that is in direct contact with the fourth portion 31Db of the second channel region 31D. The second gate electrode 52 can overlap the second channel region 31D.

The gate connecting electrode 54 can be disposed over another portion of the first slope portion 41A-1′ of the first gate insulating layer 41′ that is in direct contact with the first slope 20S1 of the buffer layer 20. The gate connecting electrode 54 can be disposed over another portion of the first horizontal portion 41B-1′ of the first gate insulating layer 41′ that is in direct contact with the top surface of the substrate 10. The gate connecting electrode 54 can be disposed over another portion of the second slope portion 41A-2′ of the first gate insulating layer 41′ that is in direct contact with the second slope 20S2 of the buffer layer 20. The gate connecting electrode 54 can be disposed over another portion of the second horizontal portion 41B-2′ of the first gate insulating layer 41′ that is in direct contact with the top surface of the substrate 10. The gate connecting electrode 54 can be disposed over the third slope portion 41A-3′, the third horizontal portion 41B-3′, the fourth slope portion 41A-4′, and the fourth horizontal portion 41B-4′ of the first gate insulating layer 41′.

A gate connecting line 55 can be disposed over the extension portion 41C of the first gate insulating layer 41′. The gate connecting line 55 can extend to the open area OP to be connected to the gate connecting electrode 54. The gate connecting line 55 may not overlap the active pattern 31′.

The first and second gate electrodes 51 and 52, the gate connecting electrode 54, and the gate connecting line 55 can be formed of the same material. The first and second gate electrodes 51 and 52, gate connecting electrode 54, and gate connecting line 55 can be implemented using one of various metallic materials, such as molybdenum (Mo), aluminum (Al), chromium (Cr), gold (Au), titanium (Ti), nickel (Ni), neodymium (Nd), or copper (Cu), an alloy of one or more thereof, or multiple layers thereof, but are not limited thereto.

The gate connecting electrode 54 can be commonly connected to the first gate electrode 51 and the second gate electrode 52. In such a case, the first gate electrode 51 and the second gate electrode 52 can be connected to each other through the gate connecting electrode 54.

In the present disclosure, the gate connecting electrode 54 is commonly connected to the first gate electrode 51 and the second gate electrode 52, but it is not intended to be limiting. The gate connecting electrode 54 can also be separately connected to each of the first gate electrode 51 and the second gate electrode 52. In this case, the first gate electrode 51 and the second gate electrode 52 can be electrically isolated.

The first and second gate electrodes 51 and 52, the gate connecting electrode 54, and the gate connecting line 55 can be formed by forming a gate electrode layer, forming a mask pattern covering a portion of the surroundings of the open area OP, and etching the gate electrode layer using the mask pattern as an etch mask.

In the etching process, the gate electrode layer masked by the first, second, third, and fourth slope portions 41A-1′, 41A-2′, 41A-3′, and 41A-4′ of the first gate insulating layer 41′ can remain unetched to form the first and second gate electrodes 51 and 52 and the gate connecting electrode 54. In the etching process, the gate electrode layer covered with the mask pattern can remain without being etched, thereby forming the gate connecting line 55.

The first thin-film transistor TR1 can include the first gate electrode 51, the first slope portion 41A-1′, and the first horizontal portion 41B-1′ of the first gate insulating layer 41′ under the first gate electrode 51, the first channel region 31A of the first active pattern 31′, and the first and second conductorization regions 31B and 31C.

The second thin-film transistor TR2 can include the second gate electrode 52, the second slope portion 41A-2′ and the second horizontal portion 41B-2′ of the first gate insulating layer 41′ under the second gate electrode 52, the second channel region 31D of the first active pattern 31′, and the second and third conductorization regions 31C and 31E of the first active pattern 31′.

A portion of the first conductorization region 31B can be self-aligned with the first slope portion 41A-1′ of the first gate insulating layer 41′. A portion of the second conductorization region 31C can be self-aligned with the first horizontal portion 41B-1′ of the first gate insulating layer 41′, and another portion of the second conductorization region 31C can be self-aligned with the second horizontal portion 41B-2′ of the first gate insulating layer 41′. A portion of the third conductorization region 31E can be self-aligned with the second slope portion 41A-2′ of the first gate insulating layer 41′.

The first conductorization region 31B may not overlap the first gate electrode 51, or only a portion of the first conductorization region 31B can overlap the first gate electrode 51. The third conductorization region 31E may not overlap the second gate electrode 52, or only a portion of the third conductorization region 31E can overlap the second gate electrode 52. The second conductorization region 31C may not overlap the first or second gate electrode 51 or 52.

By disposing the first gate electrode 51 over the first slope portion 41A-1′ and the first horizontal portion 41B-1′ of the first gate insulating layer 41′ and configuring the first conductorization region 31B and the second conductorization region 31C to be self-aligned with the first slope portion 41A-1′ and the first horizontal portion 41B-1′ of the first gate insulating layer 41′, the area where the first and second conductorization regions 31B and 31C overlap the first gate electrode 51 can be minimized. Accordingly, parasitic capacitance between the first gate electrode 51 and the first and second conductorization regions 31B and 31C can be minimized, and the breakdown characteristics of the first thin-film transistor TR1 can be improved.

Similarly, by disposing the second gate electrode 52 over the second slope portion 41A-2′ and the second horizontal portion 41B-2′ of the first gate insulating layer 41′ and configuring the second conductorization region 31C and the third conductorization region 31E to be self-aligned with the second slope portion 41A-2′ and the second horizontal portion 41B-2′ of the first gate insulating layer 41′, the area where the second and third conductorization regions 31C and 31E overlap the second gate electrode 52 can be minimized. Accordingly, the parasitic capacitance between the second gate electrode 52 and the second and third conductorization regions 31C and 31E can be minimized, and the breakdown characteristics of the second thin-film transistor TR2 can be improved.

An insulating layer 60 can be disposed over the buffer layer 20 to cover the first active pattern 31′, the first gate insulating layer 41′, the first and second gate electrodes 51 and 52, the gate connecting electrode 54, and the gate connecting line 55. The insulating layer 60 can have a first contact hole CH1 exposing the first conductorization region 31B, a second contact hole CH2 exposing the second conductorization region 31C, and a third contact hole CH3 exposing the third conductorization region 31E.

The first, second, and third electrodes 71, 72, and 73 can be disposed over the insulating layer 60.

The first electrode 71 can be connected to the first conductorization region 31B through the first contact hole CH1. The second electrode 72 can be connected to the second conductorization region 31C through the second contact hole CH2. The third electrode 73 can be connected to the third conductorization region 31E through the third contact hole CH3.

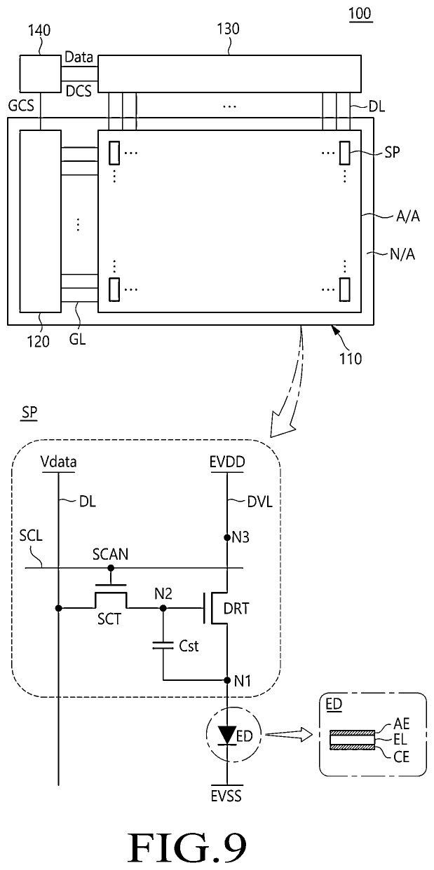

FIG. 9 illustrates a schematic configuration of a system of a display device according to embodiments of the present disclosure.

Referring to FIG. 9, according to embodiments of the present disclosure, a display device 100 includes a display panel 110. In addition, the display device 100 includes a driver circuit for driving various signal lines or the like disposed on the display panel 110. The driving circuitry can include a gate driver circuit 120, a data driver circuit 130, a controller 140, and the like.

The display panel 110 includes an active area A/A and a non-active area N/A outside the active area A/A. A plurality of sub-pixels SP are disposed in the active area A/A of the display panel 110. A plurality of gate lines GL extending in a first direction (e.g., a column direction or a row direction) and a plurality of data lines DL extending in a second direction intersecting the first direction can be disposed on the display panel 110, and the sub-pixels SP can be disposed in areas where the gate lines GL and the data lines DL intersect.

The gate driver circuit 120 can generate gate signals and output the gate signals to a plurality of gate lines GL. As shown in FIG. 9, the gate driver circuit 120 can be disposed in the non-active area N/A of the display panel 110. That is, the display device 100 can be a gate-in-panel (GIP) display device.

The gate driver circuit 120 can be formed separately from the display panel 110 and connected to the display panel 110 by a tape automated bonding (TAB) method or to bonding pads on the display panel 110 by a chip-on-glass (COG) method or a chip-on-plastic (COP) method, or can be implemented and connected to the display panel 110 by a chip-on-film (COF) method.

The data driver circuit 130 can output data signals (also referred to as “data voltages”) corresponding to a video or image signal to the plurality of data lines DL. The data driver circuit 130 can include one or more source driver integrated circuits. For example, the respective source driver integrated circuits can be connected to the display panel 110 by the TAB method, connected to bonding pads on the display panel 110 by the COG or COP method, or implemented and connected to the display panel 110 by the COF method.

In FIG. 9, the data driver circuit 130 is shown as a separate component from display panel 110, but the data driver circuit 130 can be configured as an in-panel type in which the data driver circuit 130 is integrally formed with display panel 110. The data driver circuit 130 can be disposed in the non-active area N/A of the display panel 110.

The controller 140 can convert input image data (or video data) input from an external host into a data signal format used by the data driver circuit 130 and supply the converted image data to the data driver circuit 130.

Each of the sub-pixels SP can include an emitting element ED and a pixel driver circuit for driving the emitting element ED. The pixel driver circuit can include a driving transistor DRT, a scan transistor SCT, and a storage capacitor Cst.

The emitting element ED can be, for example, an organic light-emitting diode (OLED), a light-emitting diode (LED) based on an inorganic material, or a quantum dot light-emitting element, which is a self-luminous semiconductor crystal.

According to embodiments of the present disclosure, when the display device 100 is an OLED display, each sub-pixel SP can include a self-luminous OLED as an emitting element. According to embodiments of the present disclosure, when the display device 100 is a quantum dot display, each sub-pixel SP can include an emitting element formed of a quantum dot, which is a self-luminous semiconductor crystal. According to embodiments of the present disclosure, when the display device 100 is a micro LED display, each sub-pixel SP can include a self-luminous micro light-emitting diode (micro LED) based on an inorganic material as a light emitting element.

The driving transistor DRT is a transistor for driving the emitting element ED by controlling current flowing to the emitting element ED, and can include a first node N1, a second node N2, a third node N3, and the like. The first node N1 can be a source or drain node and electrically connected to an anode electrode AE of the emitting element ED. The second node N2 can be a gate node and electrically connected to a source or drain node of the scan transistor SCT. The third node N3 can be a drain or source node and connected to a drive voltage line DVL through which a drive voltage EVDD is supplies.

The scan transistor SCT can control the connection between the data line DL and the second node N2 of the driving transistor DRT. The scan transistor SCT can connect the second node N2 of the driving transistor DRT with a corresponding data line DL of the plurality of data lines DL in response to a scan signal SCAN supplied to a scan line SCL, i.e., a type of gate line GL. The scan transistor SCT can transfer a data voltage Vdata to the second node N2, which is the gate node of the driving transistor DRT, in response to the scan signal SCAN.

The storage capacitor Cst can be connected to the first node N1 and the second node N2 of the driving transistor DRT and maintain the voltage of the second node N2 for a predetermined period of time.

Each sub-pixel SP can have, for example, a 2T1C structure including two transistors DRT and SCT and a single capacitor Cst as shown in FIG. 9, but is not limited thereto. In some cases, each sub-pixel SP can further include one or more transistors and/or one or more capacitors.

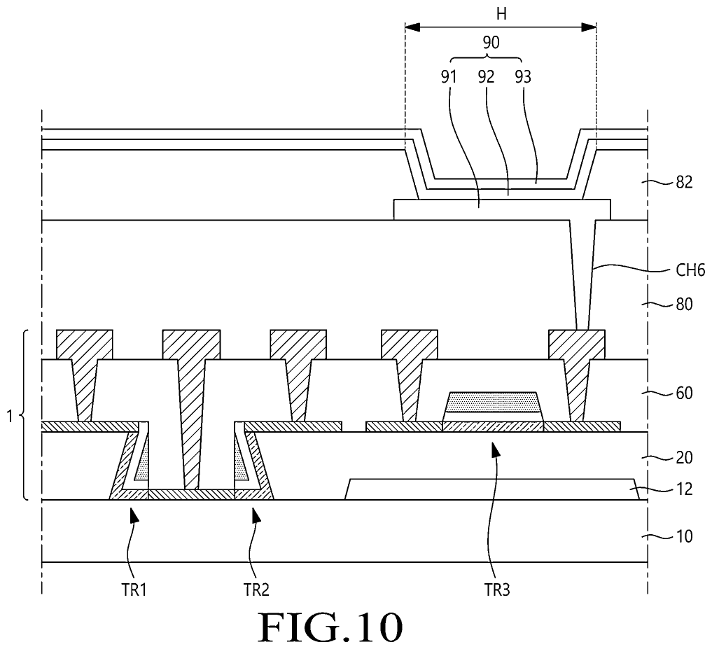

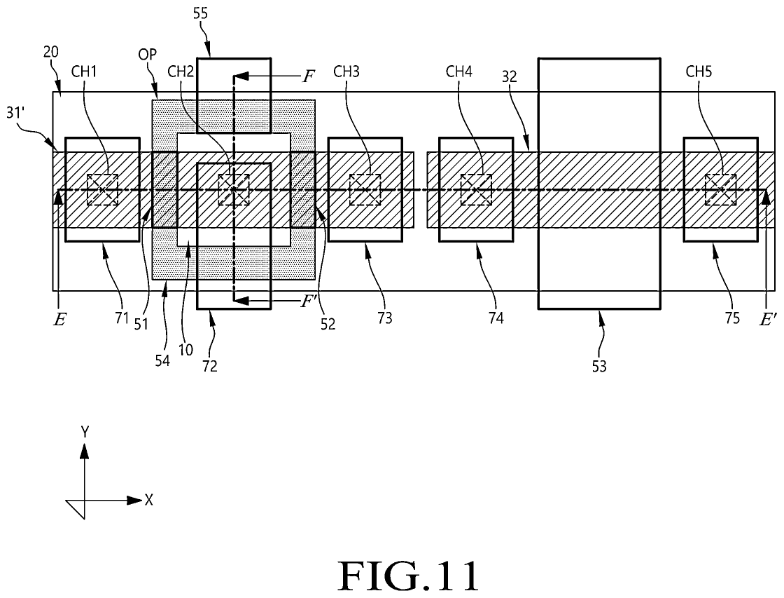

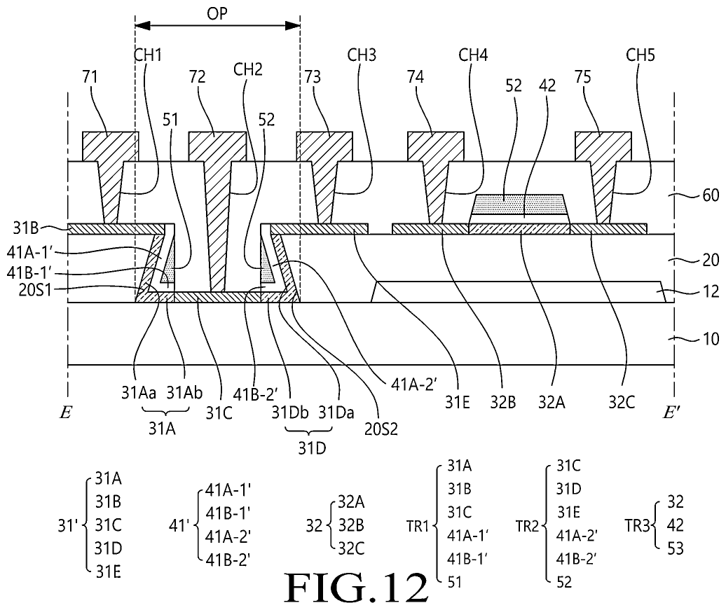

FIG. 10 is a cross-sectional view illustrating a display device according to embodiments of the present disclosure, FIG. 11 is a plan view illustrating a circuit element layer of the display device according to embodiments of the present disclosure, and FIG. 12 is a cross-sectional view taken along line E-E′ in FIG. 11.

Referring now to FIG. 10, according to embodiments of the present disclosure, the display device can include a circuit element layer 1 disposed over a substrate 10 and an emitting element 90 disposed on the circuit element layer 1.

The substrate 10 can include a variety of materials having flexible or bendable properties. For example, the substrate 10 can include glass, metal, or polymer resin. In addition, the substrate 10 can include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 10 can be modified variously, such as having a multilayer structure including two layers each including the polymer resin described above and a barrier layer including an inorganic material (such as silicon oxide, silicon nitride, or silicon oxynitride) provided between the layers.

Further auxiliary films, for example, a barrier film, a blocking film, and/or a buffer film, can be disposed over the substrate 10. The auxiliary film can smooth the top surface and prevent the penetration of impurities. The auxiliary film can be formed of an inorganic insulating material and can be formed in a single-layer structure or a double-layer structure (or a monolayer or bilayer structure). The auxiliary film can prevent first and second active patterns 31′ and 32 (see FIG. 12) from being contaminated by impurities from the substrate 10, thereby protecting the first and second active patterns 31′ and 32 while improving interfacial properties thereof.

The circuit element layer 1 can include a first thin-film transistor TR1 described above with reference to FIGS. 1 through 5. The circuit element layer 1 can include first and second thin-film transistors TR1 and TR2, described above with reference to FIGS. 6 through 8. In addition, or in another example, the circuit element layer 1 can further include a third thin-film transistor TR3.

The first, second, and third thin-film transistors TR1, TR2, and TR3 can be transistors included in the sub-pixel. For example, the first thin-film transistor TR1 or the second thin-film transistor TR2 can be a switching transistor, and the third thin-film transistor TR3 can be a driving transistor, but it is not intended to be limiting.

Referring to FIGS. 11 and 12, the third thin-film transistor TR3 can include a second active pattern 32, a second gate insulating layer 42, and a third gate electrode 53. The third thin-film transistor TR3 can have a coplanar structure.

The second active pattern 32 can be disposed over the top surface of the buffer layer 20. The second active pattern 32 can include an oxide semiconductor.

The second active pattern 32 can include a third channel region 32A, and a fourth conductorization region 32B and a fifth conductorization region 32C on opposite sides of the third channel region 32A. The third channel region 32A can have semiconductor properties. The third channel region 32A can be formed of a semiconductor, for example, an intrinsic oxide semiconductor. The fourth conductorization region 32B and the fifth conductorization region 32C can be regions where the oxide semiconductor has been conductorized by exposure to an etch gas used in the etching process to form the second gate insulating layer 42. One of the fourth conductorization region 32B and the fifth conductorization region 32C can be a source region of the third thin-film transistor TR3, and the other can be a drain region of the third thin-film transistor TR3.

The second gate insulating layer 42 can be disposed over the third channel region 32A. The second gate insulating layer 42 can cover the third channel region 32A and expose the fourth conductorization region 32B and the fifth conductorization region 32C. The third gate electrode 53 can be disposed over the second gate insulating layer 42.

The circuit element layer 1 can further include a bottom shield metal pattern 12 disposed over the substrate 10. The bottom shield metal pattern 12 can be disposed in a region corresponding to the third thin-film transistor TR3. The bottom shield metal pattern 12 can include molybdenum (Mo). The bottom shield metal pattern 12 can prevent potential generation on the surface of the substrate 10 and light from entering from the outside.

The circuit element layer 1 can include an insulating layer 60. The insulating layer 60 can be disposed over the buffer layer 20 and can cover the first, second, and third thin-film transistors TR1, TR2, and TR3.

The insulating layer 60 can be provided with first, second, third, fourth, and fifth contact holes CH1, CH2, CH3, CH4, and CH5 exposing the first, second, third, fourth, and fifth conductorization regions 31B, 31C, 31E, 32B, and 32C, respectively.

First, second, third, fourth, and fifth electrodes 71, 72, 73, 74, and 75 can be disposed over the insulating layer 60. The first electrode 71 can be connected to the first conductorization region 31B through the first contact hole CH1. The second electrode 72 can be connected to the second conductorization region 31C through the second contact hole CH2. The third electrode 73 can be connected to the third conductorization region 31E through the third contact hole CH3. The fourth electrode 74 can be connected to the fourth conductorization region 32B through the fourth contact hole CH4. The fifth electrode 75 can be connected to the fifth conductorization region 32C through the fifth contact hole CH5.

Referring again to FIG. 10, a passivation layer 80 can be disposed over the insulating layer 60 to cover the first, second, third, fourth, and fifth electrodes 71, 72, 73, 74, and 75. A sixth contact hole CH6 exposing the fifth electrode 75 to the passivation layer 80 can be provided.

The emitting element 90 can be provided over the passivation layer 80.

The emitting element 90 can include a pixel electrode 91, a light-emitting layer 92, and a common electrode 93. The pixel electrode 91 can be disposed over the passivation layer 80 and connected to the fifth electrode 75 through the sixth contact hole CH6.

A bank 82 can be disposed over the passivation layer 80. The bank 82 can have a hole H exposing the pixel electrode 91. The emitting element 90 can be formed in the region exposed by the hole H. The bank 82 can include an organic material, for example, polyimide or hexamethyldisiloxane (HMDSO).

The light-emitting layer 92 can be disposed over the pixel electrode 91 exposed through the hole H of the bank 82. The light-emitting layer 92 can cover a side surface of the bank 82 exposed through the hole H and the top surface of the bank 82.

The light-emitting layer 92 can include an organic material including a fluorescent or phosphorescent material that emits red, green, blue, or white light. The light-emitting layer 92 can be a low molecular weight organic material or a high molecular weight organic material.

In addition, or in another example, a first functional layer and a second functional layer can be selectively disposed under and over the light-emitting layer 92. The first functional layer can include a hole injection layer (HIL) and/or a hole transport layer (HTL), and the second functional layer can include an electron transport layer (ETL) and/or an electron injection layer (EIL).

The common electrode 93 can be disposed over the light-emitting layer 92.

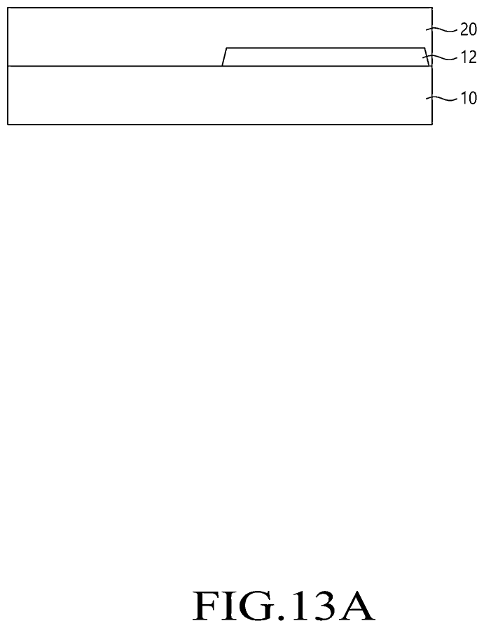

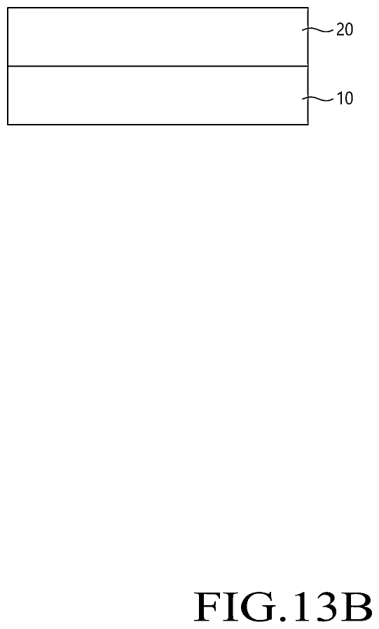

FIGS. 13A through 19B are cross-sectional views illustrating a method of fabricating a circuit element layer of a display device according to embodiments of the present disclosure. Here, FIGS. 13A, 14A, 15A, 16A, 17A, 18A and 19A illustrate cross-sections corresponding to line E-E′ in FIG. 11, and FIGS. 13B, 14B, 15B, 16B, 17B, 18B and 19B illustrate cross-sections corresponding to lines F-F′ in FIG. 11.

Referring to FIGS. 13A and 13B, a bottom shield metal pattern 12 can be formed over the substrate 10, and a buffer layer 20 can be formed to cover the bottom shield metal pattern 12.

An additional auxiliary film, such as a barrier film, a blocking film, and/or a buffer film, can be disposed over the substrate 10.

The bottom shield metal pattern 12 can be formed in the third thin-film transistor region.

The buffer layer 20 can include, but is not limited to, a single layer formed of an inorganic material, such as silicon nitride (SiNx) or silicon oxide (Siox), or multiple layers of silicon nitride (SiNx) and silicon oxide (Siox).

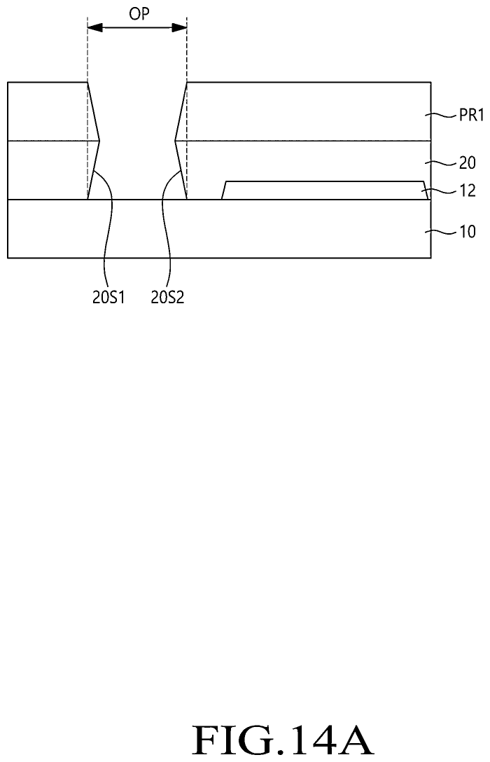

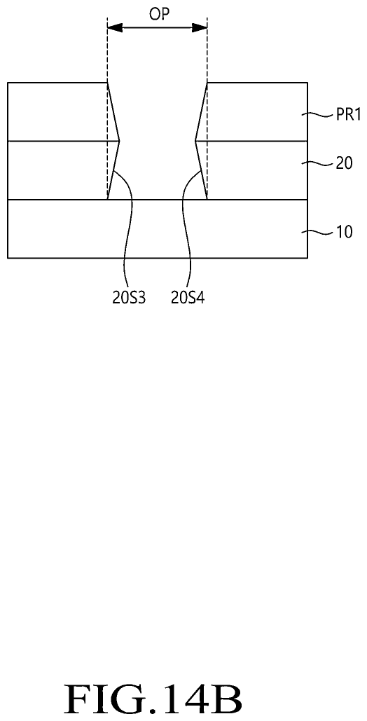

Referring to FIGS. 14A and 14B, an open area OP can be formed in the buffer layer 20.

A first mask pattern PR1 exposing portions of the first and second thin-film transistor regions of the buffer layer 20 can be formed over the buffer layer 20, and an open area OP can be formed by etching the buffer layer 20 using the first mask pattern PR1 as an etch mask. The etching process can be implemented as a wet etching process.

The slopes 20S1, 20S2, 20S3, and 20S4 of the buffer layer 20 can be exposed by the open area OP. The slopes 20S1, 20S2, 20S3, and 20S4 can include first and second slopes 20S1 and 20S2 facing each other in the X-axis direction and third and fourth slopes 20S3 and 20S4 facing each other in the Y-axis direction. The width of the open area OP can increase in the direction toward the substrate 10. The first, second, third, and fourth slopes 20S1, 20S2, 20S3, and 20S4 can have an inverted tapered shape.

The first mask pattern PR1 can be formed of a photoresist, and the first mask pattern PR1 remaining after the formation of the open area OP can be removed by a stripping process.

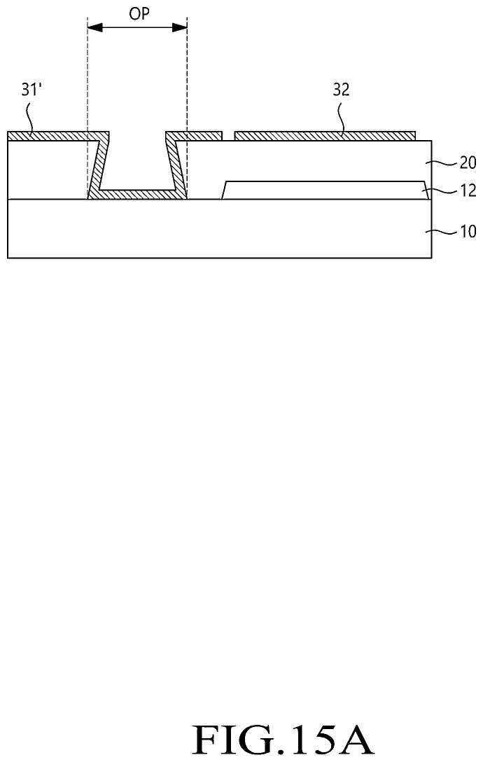

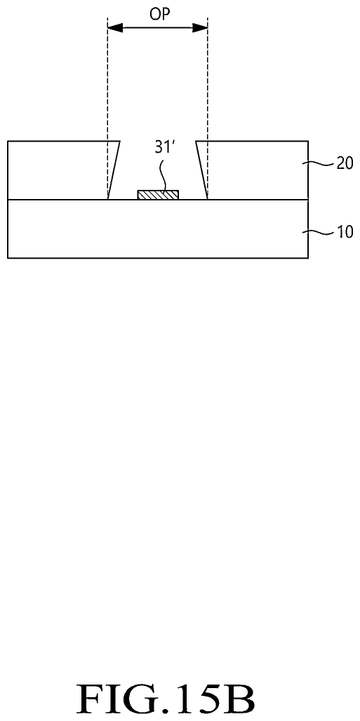

Referring to FIGS. 15A and 15B, an active layer can be formed, and the active layer can be patterned to form a first active pattern 31′ in the first and second thin-film transistor regions. In the process of forming the first active pattern 31′, a second active pattern 32 can be formed in the third thin-film transistor region. The first active pattern 31′ and the second active pattern 32 can be formed at one time.

The first active pattern 31′ can be disposed continuously over the top surface of the buffer layer 20 adjacent to the first slope 20S1, the first slope 20S1, the top surface of the substrate 10 between the first slope 20S1 and the second slope 20S2, the second slope 20S2, and the top surface of the buffer layer 20 adjacent to the second slope 20S2. The second active pattern 32 can be formed over the top surface of the buffer layer 20.

The active layer can be formed by an ALD process. Since the active layer is formed using the ALD process with excellent step coverage, the first and second active patterns 31′ and 32 can be formed with a uniform thickness along the surface curvatures of the first and second slopes 20S1 and 20S2, the top surface of the buffer layer 20, and the top surface of the substrate 10.

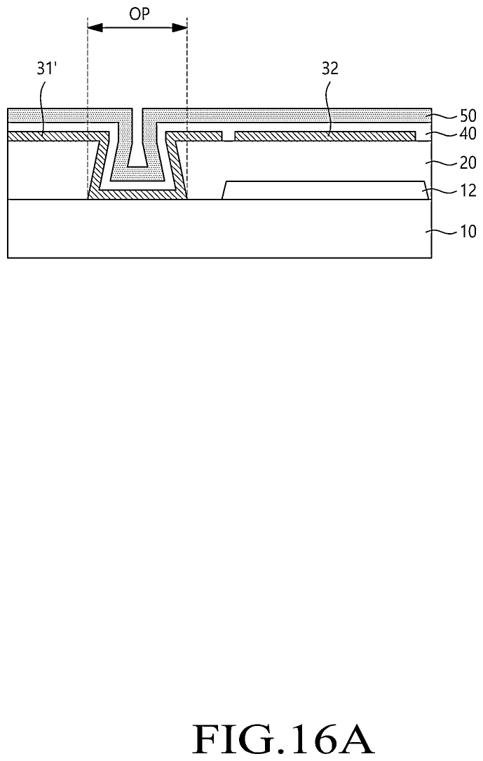

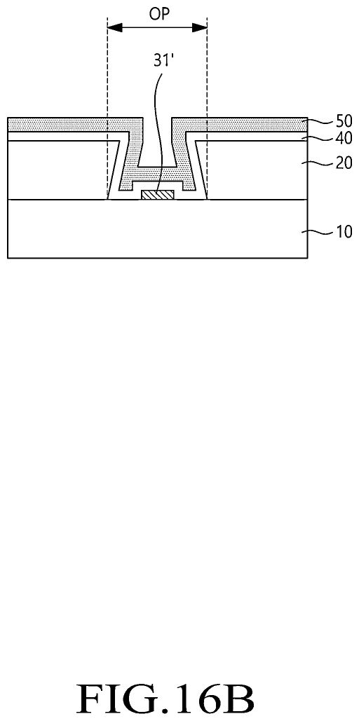

Referring to FIGS. 16A and 16B, a gate insulating layer 40 can be formed over the first and second active patterns 31′ and 32, the first, second, third, and fourth slopes 20S1, 20S2, 20S3, and 20S4 of the buffer layer 20, the top surface of the buffer layer 20, and the top surface of the substrate 10, and a gate electrode layer 50 can be formed over the gate insulating layer 40.

The gate insulating layer 40 can be formed of silicon oxide (SiO₂). However, the gate insulating layer 40 is not limited thereto, and can be formed of an inorganic insulating material other than silicon oxide (SiO₂), and can have a single-layer structure or a double-layer structure.

The gate electrode layer 50 can be formed of a metallic material and can have a single-layer structure or a double-layer structure. The gate electrode layer 50 implemented using one of various metallic materials, such as molybdenum (Mo), aluminum (Al), chromium (Cr), gold (Au), titanium (Ti), nickel (Ni), neodymium (Nd), or copper (Cu), an alloy of one or more thereof, or multiple layers thereof, but are not limited thereto.

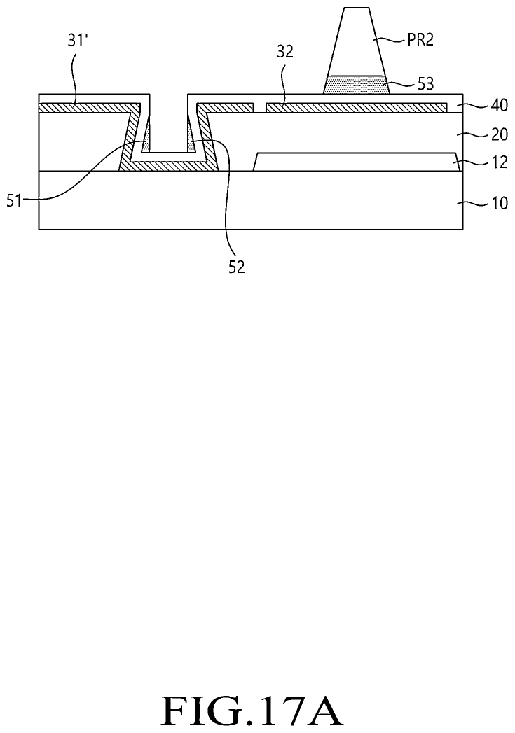

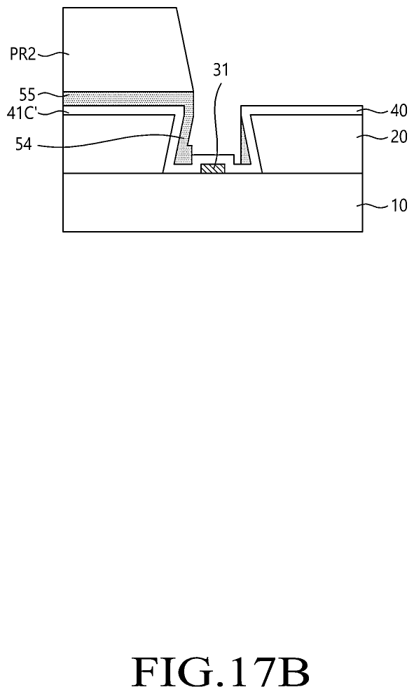

Referring to FIGS. 17A and 17B, a second mask pattern PR2 can be formed over the gate electrode layer 50, and first, second, and third gate electrodes 51, 52, 53, a gate connecting electrode 54, and a gate connecting line 55 can be formed by etching the gate electrode layer 50 using the second mask pattern PR2 as an etch mask. The first, second, and third gate electrodes 51, 52, and 53, the gate connecting electrode 54, and the gate connecting line 55 can be formed at one time.

The second mask pattern PR2 can expose the open area OP and cover a portion of the gate electrode layer 50 around the open area OP. In addition, the second mask pattern PR2 can cover a portion of the third thin-film transistor region.

The first gate electrode 51, the second gate electrode 52, and the gate connecting electrode 54 can be formed of remaining portions of the gate electrode layer 50 that are covered with the slope portions of the first gate insulating layer 41′ disposed over the first, second, third, and fourth slopes 20S1, 20S2, 20S3, and 20S4 of the buffer layer 20 and are not removed in the above etching process.

The third gate electrode 53 can be formed of a remaining portion of the gate electrode layer 50 in the third thin-film transistor area that is covered with the second mask pattern PR2 and is not removed in the etching process. The gate connecting line 55 can be formed of a remaining portion of the gate electrode layer 50 around the open area OP that is covered with the second mask pattern PR2 and is not removed in the etching process.

The second mask pattern PR2 can be formed of a photoresist, and the second mask pattern PR2 remaining after the formation of the first, second, and third gate electrodes 51, 52, 53, the gate connecting electrode 54, and the gate connecting line 55 can be removed by a stripping process.

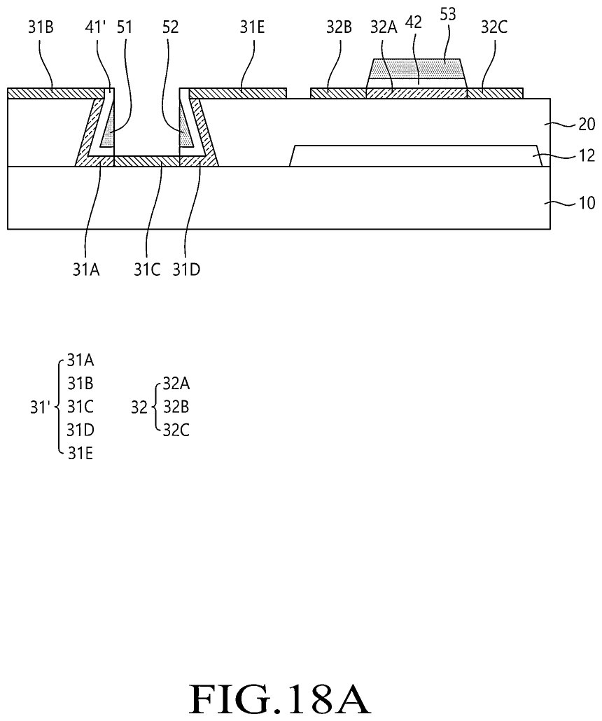

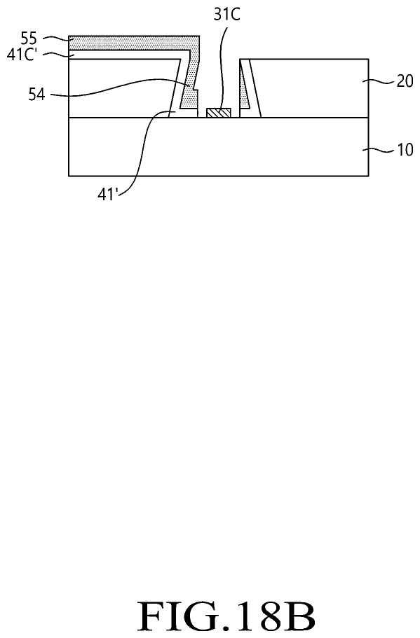

Referring to FIGS. 18A and 18B, the gate insulating layer 40 exposed by the first and second gate electrodes 51 and 52 and the gate connecting electrode 54 can be removed by an etching process to form the first and second gate insulating layers 41′ and 42. The first gate insulating layer 41′ and the second gate insulating layer 42 can be formed at one time.

The etching process can be implemented as a dry etching process. In the dry etching process, the first and second active patterns 31′ and 32 can be conductorized by exposure to the etching gas, except for portions covered with the first, second, and third gate electrodes 51, 52, and 53. As a result, a first conductorization region 31B, a second conductorization region 31C, and a third conductorization region 31E can be formed in the first active pattern 31′, and a fourth conductorization region 32B and a fifth conductorization region 32C can be formed in the second active pattern 32. The first, second, third, fourth, and fifth conductorization regions 31B, 31C, 31E, 32B, and 32C can be formed at one time.

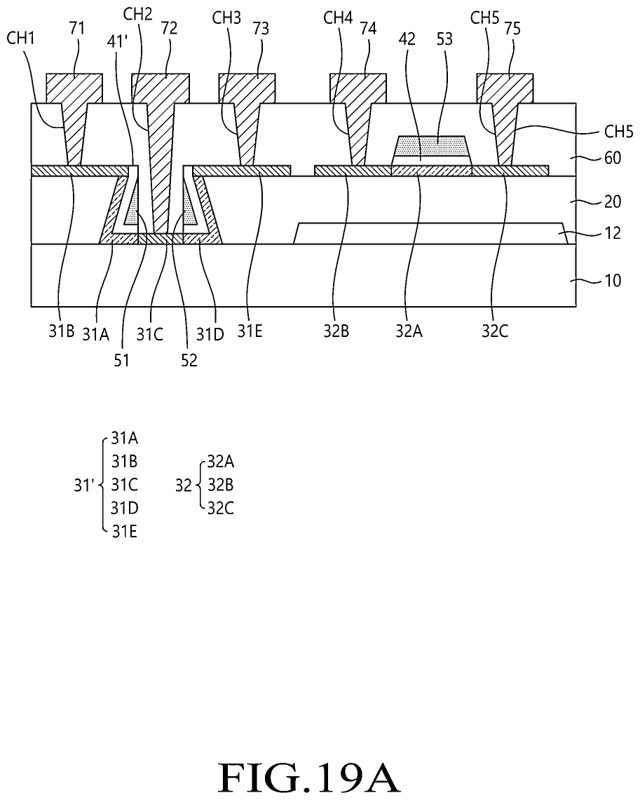

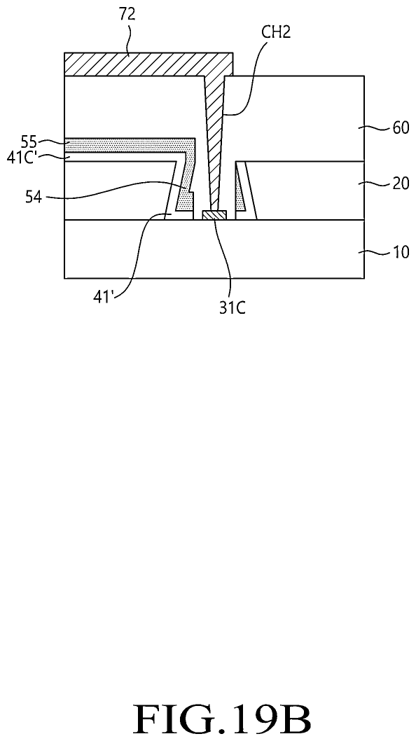

Referring to FIGS. 19A and 19B, an insulating film 60 covering the first and second active patterns 31′ and 32, the first and second gate insulating layers 41′, 42, the first, second, and third gate electrodes 51, 52, and 53, the gate connecting electrode 54, and the gate connecting line 55 can be formed over the buffer layer 20.

Thereafter, a first contact hole CH1 exposing the first conductorization region 31B, a second contact hole CH2 exposing the second conductorization region 31C, and a third contact hole CH3 exposing the third conductorization region 31E can be formed in the insulating film 60 by a photolithography process. In addition, a fourth contact hole CH4 exposing the fourth conductorization region 32B and a fifth contact hole CH5 exposing the fifth conductorization region 32C can be formed.

Thereafter, a metal layer can be formed to cover the insulating film 60 and fill the first, second, third, fourth, and fifth contact holes CH1, CH2, CH3, CH4, and CH5, and the metal layer can be patterned to form first, second, third, fourth, and fifth contact plugs 71, 72, 73, 74, and 75 connected to the first, second, third, fourth, and fifth conductorization regions 31B, 31C, 31E, 32B, and 32C through the first, second, third, fourth, and fifth contact holes CH1, CH2, CH3, CH4, and CH5, respectively.

The thin-film transistor array substrate and the display device including the same according to embodiments of the present disclosure as described above can be briefly reviewed as follows.

According to embodiments of the present disclosure, a thin-film transistor array substrate can include a buffer layer disposed over a substrate, and including an open area exposing a portion of the substrate and a first slope having an inverted tapered shape and exposed through the open area; and a first thin-film transistor. The first thin-film transistor can include a first active pattern including a first channel region including a first portion disposed over the first slope of the buffer layer and a second portion disposed over a top surface of the substrate under the first slope of the buffer layer, a first conductorization region disposed over a top surface of the buffer layer, and a second conductorization region disposed over the top surface of the substrate; a first gate insulating layer including a first slope portion disposed over the first portion of the first channel region and a first horizontal portion disposed over the second portion of the first channel region; and a first gate electrode disposed over the first slope portion and the first horizontal portion of the first gate insulating layer and overlapping the first channel region.

According to embodiments of the present disclosure, a portion of the first conductorization region can be self-aligned with the first slope portion of the first gate insulating layer, and a portion of the second conductorization region can be self-aligned with the first horizontal portion of the first gate insulating layer.

According to embodiments of the present disclosure, the second conductorization region may not overlap the first gate electrode.

According to embodiments of the present disclosure, the first conductorization region can overlap the first slope of the buffer layer, and the second conductorization region may not overlap the first slope of the buffer layer.

According to embodiments of the present disclosure, the first conductorization region and the second conductorization region can be spaced apart from each other in a direction parallel to the top surface of the substrate.

According to embodiments of the present disclosure, a top portion of the first slope portion of the first gate insulating layer can be in contact with a side surface of the first conductorization region.

According to embodiments of the present disclosure, the first gate electrode can include an inner surface in contact with the first slope portion and the first horizontal portion of the first gate insulating layer and an outer surface opposite the inner surface, and the outer surface of the first gate electrode can be aligned perpendicular to the top portion of the first slope portion of the first gate insulating layer.

According to embodiments of the present disclosure, the first gate electrode can include an inner surface in contact with the first slope portion and the first horizontal portion of the first gate insulating layer and an outer surface opposite the inner surface, and the outer surface of the first gate electrode can protrude beyond the top portion of the first slope portion of the first gate insulating layer.

According to embodiments of the present disclosure, the first gate electrode can include an inner surface in contact with the first slope portion and the first horizontal portion of the first gate insulating layer and an outer surface opposite the inner surface, and the outer surface of the first gate electrode can have a tapered shape.

According to embodiments of the present disclosure, the first gate electrode can include an inner surface in contact with the first slope portion and the first horizontal portion of the first gate insulating layer and an outer surface opposite the inner surface. The outer surface of the first gate electrode can have curvatures corresponding to surface shapes of the first slope portion and the first horizontal portion of the first gate insulating layer.

According to embodiments of the present disclosure, a portion of the first slope portion of the first gate insulating layer can be in direct contact with the first portion of the first channel region, and another portion of the first slope portion of the first gate insulating layer can be in direct contact with the first slope of the buffer layer. A portion of the first horizontal portion of the first gate insulating layer can be in direct contact with the second portion of the first channel region, and another portion of the first horizontal portion of the first gate insulating layer can be in direct contact with the top surface of the substrate.

According to embodiments of the present disclosure, the thin-film transistor array substrate can further include a gate connecting electrode connected to the first gate electrode. The gate connecting electrode can be disposed over the other portion of the first slope portion of the first gate insulating layer and the other portion of the first horizontal portion of the first gate insulating layer.

According to embodiments of the present disclosure, the gate connecting electrode can be formed of the same material as the first gate electrode.

According to embodiments of the present disclosure, the gate connecting electrode can cover the first gate insulating layer over the first slope of the buffer layer.

According to embodiments of the present disclosure, the buffer layer can further include a second slope exposed through the open area, facing the first slope in a first direction, and having an inverted tapered shape. The thin-film transistor array substrate can further include a second thin-film transistor disposed over a region including the second slope of the buffer layer and sharing the second conductorization region with the first thin-film transistor.

According to embodiments of the present disclosure, the first active pattern can further include a second channel region including a third portion disposed over the second slope of the buffer layer and a fourth portion disposed over the top surface of the substrate under the second slope of the buffer layer and a third conductorization region disposed over the top surface of the buffer layer. The first gate insulating layer can further include a second slope portion disposed over the third portion of the second channel region and a second horizontal portion disposed over the fourth portion of the second channel region. The second thin-film transistor can include the second channel region, the second conductorization region, and the third conductorization region of the first active pattern; the second slope portion and the second horizontal portion of the first gate insulating layer; and a second gate electrode disposed over the second slope portion and the second horizontal portion of the first gate insulating layer and overlapping the second channel region.

According to embodiments of the present disclosure, a portion of the first conductorization region can be self-aligned with the first slope portion of the first gate insulating layer, a portion of the second conductorization region can be self-aligned with the first horizontal portion of the first gate insulating layer, another portion of the second conductorization region can be self-aligned with the second horizontal portion of the first gate insulating layer, and a portion of the third conductorization region can be self-aligned with the second slope portion of the first gate insulating layer.

According to embodiments of the present disclosure, the second conductorization region may not overlap the first or second gate electrode.

According to embodiments of the present disclosure, the first conductorization region can overlap the first slope of the buffer layer, the third conductorization region can overlap the second slope of the buffer layer, and the second conductorization region may not overlap the first or second slope of the buffer layer.

According to embodiments of the present disclosure, the first conductorization region, the second conductorization region, and the third conductorization region can be spaced apart from each other in a direction parallel to the top surface of the substrate.

According to embodiments of the present disclosure, a portion of the first slope portion of the first gate insulating layer can be in direct contact with the first portion of the first channel region, and another portion of the first slope portion of the first gate insulating layer can be in direct contact with the first slope of the buffer layer. A portion of the first horizontal portion of the first gate insulating layer can be in direct contact with the second portion of the first channel region, and another portion of the first horizontal portion of the first gate insulating layer can be in direct contact with the top surface of the substrate. A portion of the second slope portion of the first gate insulating layer can be in direct contact with the third portion of the second channel region, and another portion of the second slope portion of the first gate insulating layer can in direct contact with the second slope of the buffer layer. A portion of the second horizontal portion of the first gate insulating layer can be in direct contact with the fourth portion of the second channel region, and another portion of the second horizontal portion of the first gate insulating layer can be in direct contact with the top surface of the substrate.

According to embodiments of the present disclosure, the buffer layer can further include third and fourth slopes exposed through the open area, facing each other in a second direction intersecting the first direction, and having an inverted tapered shape. The first gate insulating layer can further include a third slope portion disposed over the third slope of the buffer layer, a third horizontal portion disposed over the substrate under the third slope portion, a fourth slope portion disposed over the fourth slope of the buffer layer, and a fourth horizontal portion disposed over the substrate under the fourth slope portion.

According to embodiments of the present disclosure, the thin-film transistor array substrate can further include a gate connecting electrode connected to the first gate electrode and the second gate electrode. The gate connecting electrode can be disposed over the other portion of the first slope portion of the first gate insulating layer, the other portion of the first horizontal portion of the first gate insulating layer, the other portion of the second slope portion of the first gate insulating layer, the other portion of the second horizontal portion of the first gate insulating layer, the third slope portion of the first gate insulating layer, the third horizontal portion of the first gate insulating layer, the fourth slope portion of the first gate insulating layer, and the fourth horizontal portion of the first gate insulating layer.

According to embodiments of the present disclosure, the gate connecting electrode can be formed of the same material as the first and second gate electrodes.

According to embodiments of the present disclosure, the thin-film transistor array substrate can include a gate connecting line disposed over the buffer layer and connected to the gate connecting electrode.

According to embodiments of the present disclosure, the first gate insulating layer can further include an extension portion disposed between the buffer layer and the gate connecting line.

According to embodiments of the present disclosure, the gate connecting line may not overlap the first active pattern.

According to embodiments of the present disclosure, a display device can include a circuit element layer disposed over a substrate; and an emitting element disposed over the circuit element layer. The circuit element layer can include a buffer layer disposed over the substrate, and including an open area exposing a portion of the substrate and a first slope having an inverted tapered shape and exposed through the open area; and a first thin-film transistor. The first thin-film transistor can include a first active pattern including a first channel region including a first portion disposed over the first slope of the buffer layer and a second portion disposed over a top surface of the substrate under the first slope of the buffer layer, a first conductorization region disposed over a top surface of the buffer layer, and a second conductorization region disposed over the top surface of the substrate; a first gate insulating layer including a first slope portion disposed over the first portion of the first channel region and a first horizontal portion disposed over the second portion of the first channel region; and a first gate electrode disposed over the first slope portion and the first horizontal portion of the first gate insulating layer and overlapping the first channel region.

According to embodiments of the present disclosure, a portion of the first conductorization region can be self-aligned with the first slope portion of the first gate insulating layer, and a portion of the second conductorization region can be self-aligned with the first horizontal portion of the first gate insulating layer.

According to embodiments of the present disclosure, the second conductorization region may not overlap the first gate electrode.

According to embodiments of the present disclosure, the first conductorization region can overlap the first slope of the buffer layer, and the second conductorization region may not overlap the first slope of the buffer layer.

According to embodiments of the present disclosure, the buffer layer can further include a second slope exposed through the open area, facing the first slope in a first direction, and having an inverted tapered shape. The circuit element layer can further include a second thin-film transistor disposed over a region including the second slope of the buffer layer and sharing the second conductorization region with the first thin-film transistor.

According to embodiments of the present disclosure, the first active pattern can further include a second channel region including a third portion disposed over the second slope of the buffer layer and a fourth portion disposed over the top surface of the substrate under the second slope of the buffer layer and connected to the second conductorization region and a third conductorization region disposed over the top surface of the buffer layer. The first gate insulating layer can further include a second slope portion disposed over the third portion of the second channel region and a second horizontal portion disposed over the fourth portion of the second channel region. The second thin-film transistor can include the second channel region, the second conductorization region, and the third conductorization region of the first active pattern; the second slope portion and the second horizontal portion of the first gate insulating layer; and a second gate electrode disposed over the second slope portion and the second horizontal portion of the first gate insulating layer and overlapping the second channel region.

According to embodiments of the present disclosure, wherein a portion of the first conductorization region can be self-aligned with the first slope portion of the first gate insulating layer. A portion of the second conductorization region can be self-aligned with the first horizontal) portion of the first gate insulating layer. Another portion of the second conductorization region can be self-aligned with the second horizontal portion of the first gate insulating layer. A portion of the third conductorization region can be self-aligned with the second slope portion of the first gate insulating layer.

According to embodiments of the present disclosure, the second conductorization region may not overlap the first or second gate electrode.

According to embodiments of the present disclosure, the first conductorization region can overlap the first slope of the buffer layer, the third conductorization region can overlap the second slope of the buffer layer, and the second conductorization region may not overlap the first or second slope of the buffer layer.

According to embodiments of the present disclosure, the first conductorization region, the second conductorization region, and the third conductorization region can be spaced apart from each other in a direction parallel to the top surface of the substrate.

According to embodiments of the present disclosure, the display device can further include a third thin-film transistor disposed over the buffer layer. The third thin-film transistor can include a second active pattern disposed over the buffer layer; a second gate insulating layer disposed over the second active pattern; and a second gate electrode disposed over a portion of the second gate insulating layer.

With at least one of the structures described above, according to embodiments of the present disclosure, a thin-film transistor array substrate and a display device including the same can be provided, in which parasitic capacitance can be reduced by minimizing the area where a gate electrode overlaps a conductorization region.

According to embodiments of the present disclosure, a thin-film transistor array substrate and a display device including the same can be provided, in which the breakdown characteristics of a thin-film transistor can be improved by minimizing the area where the gate electrode overlaps the conductorization region and improving the thickness uniformity of the gate insulating layer.

According to embodiments of the present disclosure, a thin-film transistor array substrate and a display device including the same can be provided, in which the resolution and performance of the display device can be improved by reducing the size of the thin-film transistor disposed in the display device while improving the characteristics of the thin-film transistor.

According to embodiments of the present disclosure, a thin-film transistor array substrate and a display device including the same can be provided, in which the number of process steps and the number of masks can be reduced by forming a vertical thin-film transistor and a co-planar thin-film transistor at the same time. Accordingly, the effect of process optimization can be achieved.

According to embodiments of the present disclosure, a thin-film transistor array substrate and a display device including the same can be provided, in which by forming a gate connecting electrode connected to the gate electrode, the resistance of the gate electrode can be reduced and the switching speed of the thin-film transistor can be improved, and the power loss occurring during the switching process can be reduced, thereby contributing to low power consumption.

The above description has been presented to enable any person skilled in the art to make and use the technical idea of the present invention, and has been provided in the context of a particular application and its requirements. Various modifications, additions and substitutions to the described embodiments of the present disclosure will be readily apparent to those skilled in the art, and the general principles defined herein can be applied to other embodiments of the present disclosure and applications without departing from the spirit and scope of the present invention. The above description and the accompanying drawings provide an example of the technical idea of the present invention for illustrative purposes only. That is, the disclosed embodiments of the present disclosure are intended to illustrate the scope of the technical idea of the present invention.

What is claimed is:

1. A thin-film transistor array substrate comprising:
a base substrate;
a buffer layer disposed over the base substrate, and comprising an open area exposing a portion of the base substrate and a first slope having an inverted tapered shape and exposed through the open area; and
a first thin-film transistor,
wherein the first thin-film transistor comprises:
a first active pattern comprising a first channel region comprising a first portion disposed over the first slope of the buffer layer and a second portion disposed over a top surface of the base substrate under the first slope of the buffer layer, a first conductorization region disposed over a top surface of the buffer layer, and a second conductorization region disposed over the top surface of the base substrate;
a first gate insulating layer comprising a first slope portion disposed over the first portion of the first channel region and a first horizontal portion disposed over the second portion of the first channel region; and
a first gate electrode disposed over the first slope portion and the first horizontal portion of the first gate insulating layer and overlapping the first channel region.

2. The thin-film transistor array substrate of claim 1, wherein a portion of the first conductorization region is self-aligned with the first slope portion of the first gate insulating layer, and
wherein a portion of the second conductorization region is self-aligned with the first horizontal portion of the first gate insulating layer.

3. The thin-film transistor array substrate of claim 1, wherein the second conductorization region does not overlap the first gate electrode.

4. The thin-film transistor array substrate of claim 1, wherein the first conductorization region overlaps the first slope of the buffer layer, and the second conductorization region does not overlap the first slope of the buffer layer.

5. The thin-film transistor array substrate of claim 1, wherein the first conductorization region and the second conductorization region are spaced apart from each other in a direction parallel to the top surface of the base substrate.

6. The thin-film transistor array substrate of claim 1, wherein a top portion of the first slope portion of the first gate insulating layer is in contact with a side surface of the first conductorization region.

7. The thin-film transistor array substrate of claim 6, wherein the first gate electrode comprises an inner surface in contact with the first slope portion and the first horizontal portion of the first gate insulating layer and an outer surface opposite the inner surface, and
wherein the outer surface of the first gate electrode is aligned perpendicular to the top portion of the first slope portion of the first gate insulating layer.

8. The thin-film transistor array substrate of claim 6, wherein the first gate electrode comprises an inner surface in contact with the first slope portion and the first horizontal portion of the first gate insulating layer and an outer surface opposite the inner surface, and
wherein the outer surface of the first gate electrode protrudes beyond the top portion of the first slope portion of the first gate insulating layer.

9. The thin-film transistor array substrate of claim 6, wherein the first gate electrode comprises an inner surface in contact with the first slope portion and the first horizontal portion of the first gate insulating layer and an outer surface opposite the inner surface, and
wherein the outer surface of the first gate electrode has a tapered shape.

10. The thin-film transistor array substrate of claim 1, wherein the first gate electrode comprises an inner surface in contact with the first slope portion and the first horizontal portion of the first gate insulating layer and an outer surface opposite the inner surface, and
wherein the outer surface of the first gate electrode has curvatures corresponding to surface shapes of the first slope portion and the first horizontal portion of the first gate insulating layer.

11. The thin-film transistor array substrate of claim 1, wherein a portion of the first slope portion of the first gate insulating layer is in direct contact with the first portion of the first channel region, and another portion of the first slope portion of the first gate insulating layer is in direct contact with the first slope of the buffer layer, and
wherein a portion of the first horizontal portion of the first gate insulating layer is in direct contact with the second portion of the first channel region, and another portion of the first horizontal portion of the first gate insulating layer is in direct contact with the top surface of the base substrate.

12. The thin-film transistor array substrate of claim 11, further comprising a gate connecting electrode connected to the first gate electrode,
wherein the gate connecting electrode is disposed over the other portion of the first slope portion of the first gate insulating layer and the other portion of the first horizontal portion of the first gate insulating layer.

13. The thin-film transistor array substrate of claim 12, wherein the gate connecting electrode is formed of a same material as the first gate electrode.

14. The thin-film transistor array substrate of claim 12, wherein the gate connecting electrode covers the first gate insulating layer over the first slope of the buffer layer.

15. The thin-film transistor array substrate of claim 1, wherein the buffer layer further comprises a second slope exposed through the open area, facing the first slope in a first direction, and having an inverted tapered shape,
wherein the thin-film transistor array substrate further comprises a second thin-film transistor disposed over a region including the second slope of the buffer layer and sharing the second conductorization region with the first thin-film transistor.

16. The thin-film transistor array substrate of claim 15, wherein the first active pattern further comprises a second channel region comprising a third portion disposed over the second slope of the buffer layer and a fourth portion disposed over the top surface of the base substrate under the second slope of the buffer layer and a third conductorization region disposed over the top surface of the buffer layer,
wherein the first gate insulating layer further comprises a second slope portion disposed over the third portion of the second channel region and a second horizontal portion disposed over the fourth portion of the second channel region, and
wherein the second thin-film transistor comprises:
the second channel region, the second conductorization region, and the third conductorization region of the first active pattern;
the second slope portion and the second horizontal portion of the first gate insulating layer; and
a second gate electrode disposed over the second slope portion and the second horizontal portion of the first gate insulating layer and overlapping the second channel region.

17. The thin-film transistor array substrate of claim 16, wherein a portion of the first conductorization region is self-aligned with the first slope portion of the first gate insulating layer,
wherein a portion of the second conductorization region is self-aligned with the first horizontal portion of the first gate insulating layer,
wherein another portion of the second conductorization region is self-aligned with the second horizontal portion of the first gate insulating layer, and
wherein a portion of the third conductorization region is self-aligned with the second slope portion of the first gate insulating layer.

18. The thin-film transistor array substrate of claim 16, wherein the second conductorization region does not overlap the first or second gate electrode.

19. The thin-film transistor array substrate of claim 16, wherein the first conductorization region overlaps the first slope of the buffer layer,
wherein the third conductorization region overlaps the second slope of the buffer layer, and
wherein the second conductorization region does not overlap the first or second slope of the buffer layer.

20. The thin-film transistor array substrate of claim 16, wherein the first conductorization region, the second conductorization region, and the third conductorization region are spaced apart from each other in a direction parallel to the top surface of the base substrate.

21. The thin-film transistor array substrate of claim 16, wherein a portion of the first slope portion of the first gate insulating layer is in direct contact with the first portion of the first channel region, and another portion of the first slope portion of the first gate insulating layer is in direct contact with the first slope of the buffer layer,
wherein a portion of the first horizontal portion of the first gate insulating layer is in direct contact with the second portion of the first channel region, and another portion of the first horizontal portion of the first gate insulating layer is in direct contact with the top surface of the base substrate,
wherein a portion of the second slope portion of the first gate insulating layer is in direct contact with the third portion of the second channel region, and another portion of the second slope portion of the first gate insulating layer is in direct contact with the second slope of the buffer layer, and
wherein a portion of the second horizontal portion of the first gate insulating layer is in direct contact with the fourth portion of the second channel region, and another portion of the second horizontal portion of the first gate insulating layer is in direct contact with the top surface of the base substrate.

22. The thin-film transistor array substrate of claim 21, wherein the buffer layer further comprises third and fourth slopes exposed through the open area, facing each other in a second direction intersecting the first direction, and having an inverted tapered shape, and
wherein the first gate insulating layer further comprises a third slope portion disposed over the third slope of the buffer layer, a third horizontal portion disposed over the base substrate under the third slope portion, a fourth slope portion disposed over the fourth slope of the buffer layer, and a fourth horizontal portion disposed over the base substrate under the fourth slope portion.

23. The thin-film transistor array substrate of claim 22, further comprising a gate connecting electrode connected to the first gate electrode and the second gate electrode,
wherein the gate connecting electrode is disposed over the other portion of the first slope portion of the first gate insulating layer, the other portion of the first horizontal portion of the first gate insulating layer, the other portion of the second slope portion of the first gate insulating layer, the other portion of the second horizontal portion of the first gate insulating layer, the third slope portion of the first gate insulating layer, the third horizontal portion of the first gate insulating layer, the fourth slope portion of the first gate insulating layer, and the fourth horizontal portion of the first gate insulating layer.

24. The thin-film transistor array substrate of claim 23, wherein the gate connecting electrode is formed of a same material as the first and second gate electrodes.

25. The thin-film transistor array substrate of claim 23, further comprising a gate connecting line disposed over the buffer layer and connected to the gate connecting electrode.

26. The thin-film transistor array substrate of claim 25, wherein the first gate insulating layer further comprises an extension portion disposed between the buffer layer and the gate connecting line.

27. The thin-film transistor array substrate of claim 25, wherein the gate connecting line does not overlap the first active pattern.

28. A display device comprising:
a substrate;
a circuit element layer disposed over the substrate; and
an emitting element disposed over the circuit element layer,
wherein the circuit element layer comprises:
a buffer layer disposed over the substrate, and comprising an open area exposing a portion of the substrate and a first slope having an inverted tapered shape and exposed through the open area; and
a first thin-film transistor,
wherein the first thin-film transistor comprises:
a first active pattern comprising a first channel region comprising a first portion disposed over the first slope of the buffer layer and a second portion disposed over a top surface of the substrate under the first slope of the buffer layer, a first conductorization region disposed over a top surface of the buffer layer, and a second conductorization region disposed over the top surface of the substrate;
a first gate insulating layer comprising a first slope portion disposed over the first portion of the first channel region and a first horizontal portion disposed over the second portion of the first channel region; and
a first gate electrode disposed over the first slope portion and the first horizontal portion of the first gate insulating layer and overlapping the first channel region.

29. The display device of claim 28, wherein a portion of the first conductorization region is self-aligned with the first slope portion of the first gate insulating layer, and
wherein a portion of the second conductorization region is self-aligned with the first horizontal portion of the first gate insulating layer.

30. The display device of claim 28, wherein the second conductorization region does not overlap the first gate electrode.

31. The display device of claim 28, wherein the first conductorization region overlaps the first slope of the buffer layer, and the second conductorization region does not overlap the first slope of the buffer layer.

32. The display device of claim 28, wherein the buffer layer further comprises a second slope exposed through the open area, facing the first slope in a first direction, and having an inverted tapered shape, and
wherein the circuit element layer further comprises a second thin-film transistor disposed over a region including the second slope of the buffer layer and sharing the second conductorization region with the first thin-film transistor.

33. The display device of claim 32, wherein the first active pattern further comprises a second channel region comprising a third portion disposed over the second slope of the buffer layer and a fourth portion disposed over the top surface of the substrate under the second slope of the buffer layer and connected to the second conductorization region and a third conductorization region disposed over the top surface of the buffer layer,
wherein the first gate insulating layer further comprises a second slope portion disposed over the third portion of the second channel region and a second horizontal portion disposed over the fourth portion of the second channel region, and
wherein the second thin-film transistor comprises:
the second channel region, the second conductorization region, and the third conductorization region of the first active pattern;
the second slope portion and the second horizontal portion of the first gate insulating layer; and
a second gate electrode disposed over the second slope portion and the second horizontal portion of the first gate insulating layer and overlapping the second channel region.

34. The display device of claim 33, wherein a portion of the first conductorization region is self-aligned with the first slope portion of the first gate insulating layer,
wherein a portion of the second conductorization region is self-aligned with the first horizontal portion of the first gate insulating layer,
wherein another portion of the second conductorization region is self-aligned with the second horizontal portion of the first gate insulating layer, and
wherein a portion of the third conductorization region is self-aligned with the second slope portion of the first gate insulating layer.

35. The display device of claim 33, wherein the second conductorization region does not overlap the first or second gate electrode.

36. The display device of claim 33, wherein the first conductorization region overlaps the first slope of the buffer layer,
wherein the third conductorization region overlaps the second slope of the buffer layer, and
wherein the second conductorization region does not overlap the first or second slope of the buffer layer.

37. The display device of claim 33, wherein the first conductorization region, the second conductorization region, and the third conductorization region are spaced apart from each other in a direction parallel to the top surface of the substrate.

38. The display device of claim 33, further comprising a third thin-film transistor disposed over the buffer layer,
wherein the third thin-film transistor comprises:
a second active pattern disposed over the buffer layer;
a second gate insulating layer disposed over the second active pattern; and
a second gate electrode disposed over a portion of the second gate insulating layer.
